(19) United States
(12) Patent Application Publication
(10) Pub. No.: US 2026/0247619 A1
(43) Pub. Date: Aug. 20, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Seung Ju OH, Icheon-si Gyeonggi-do (KR)

(73) Assignee: SK hynix Inc., Icheon-si Gyeonggi-do (KR)

(21) Appl. No.: 19/378,066

(22) Filed: Nov. 3, 2025

Related U.S. Application Data
(63) Continuation-in-part of application No. 19/202,617, filed on May 8, 2025.

(30) Foreign Application Priority Data
Feb. 18, 2025 (KR) 10-2025-0020951
Jun. 30, 2025 (KR) 10-2025-0086763

(51) Int. Cl. H10B 43/27; H10B 41/10; H10B 41/27; H10B 41/35; H10B 41/41; H10B 41/50; H10B 43/10; H10B 43/35; H10B 43/40; H10B 43/50; H10D 30/01; H10D 30/69; H10D 30/68; H10W 90/00

(52) U.S. Cl. CPC H10B 43/27; H10B 41/10; H10B 41/27; H10B 41/35; H10B 41/41; H10B 41/50; H10B 43/10; H10B 43/35; H10B 43/40; H10B 43/50; H10D 30/0411; H10D 30/693; H10D 30/0413; H10D 30/689; H10W 90/792

(57) ABSTRACT

A semiconductor device includes a stack including a plurality of first insulating layers alternately stacked with a plurality of second insulating layers, a contact plug extending through the stack, a gate structure surrounding the stack and including a plurality of conductive layers alternately stacked with the plurality of first insulating layers, a separation structure located between the stack and the gate structure, and a contact pattern extending around the separation structure, and electrically connecting the contact plug and a first conductive layer among the plurality of conductive layers.

### CROSS REFERENCE TO RELATED APPLICATION

This application is a continuation-in-part of U.S. Application number 19/202,617, filed on May 8, 2025, which claims priority under 35 U.S.C. §119(a) to Korean Patent Application No. 10-2025-0020951 filed in the Korean Intellectual Property Office on February. 18, 2025, and claims priority under 35 U.S.C. §119(a) to Korean Patent Application No. 10-2025-0086763 filed in the Korean Intellectual Property Office on June. 30, 2025, which applications are all incorporated herein by reference in their entirety.

### BACKGROUND

### 1. Technical Field

The present disclosure relates to an electronic device and a method of manufacturing the electronic device, including but not limited to a semiconductor device and a method of manufacturing the semiconductor device.

### 2. Related Art

Integration density of a semiconductor device is determined by an area occupied by a unit memory cell. As improvements in an integration density of semiconductor devices in which memory cells are formed as a single layer on a substrate reach a limit, three-dimensional semiconductor devices in which memory cells are stacked on a substrate are under development. Various structures and manufacturing methods are being developed to improve operation reliability of semiconductor devices.

### SUMMARY

According to an embodiment of the present disclosure, a semiconductor device may include a stack including a plurality of first insulating layers alternately stacked with a plurality of second insulating layers, a contact plug extending through the stack, a gate structure surrounding the stack and including a plurality of conductive layers alternately stacked with the plurality of first insulating layers, a separation structure located between the stack and the gate structure, and a contact pattern extending around the separation structure and electrically connecting the contact plug and a first conductive layer among the conductive layers.

According to an embodiment of the present disclosure, a semiconductor device may include a stack including a plurality of first insulating layers alternately stacked with a plurality of second insulating layers, a contact plug extending through the stack, a gate structure surrounding the stack and including a plurality of conductive layers alternately stacked with the plurality of first insulating layers, a separation structure located between the stack and the gate structure, and including a plurality of pillars arranged around the contact plug and a plurality of extensions interconnecting the pillars, and a contact pattern extending around the separation structure and electrically connecting the contact plug and a first conductive layer among the conductive layers.

According to an embodiment of the present disclosure, a method of manufacturing a semiconductor device may include forming a stack by alternately stacking a plurality of first material layers with a plurality of second material layers, forming a plurality of holes extending through the stack, forming a sacrificial layer in each of the plurality of holes, forming a contact hole located in a region delineated by the plurality of holes and extending through the stack, forming a first opening, through which a second material layer is exposed, by etching a surface at one end the contact hole, resulting in a contact spacer, forming a second opening, through which the sacrificial layers are exposed, by selectively removing the second material layer through the first opening, and forming a conductive material in the second opening, the first opening, and within the contact spacer.

### BRIEF DESCRIPTION OF THE DRAWINGS

FIGS. 1A, 1B, 1C and 1D illustrate a semiconductor device according to an embodiment of the present disclosure.

FIGS. 2A, 2B, and 2C illustrate a semiconductor device according to an embodiment of the present disclosure.

FIGS. 3A,3B, 3C, and 3D illustrate a semiconductor device according to an embodiment of the present disclosure.

FIGS. 4A, 4B, 5A, 5B, 5C, 6A, 6B, 6C, 7A, 7B, 7C, 8A, 8B, 8C, 8D, 9A, 9B, and 9C illustrate a semiconductor device formed utilizing a method of manufacturing a semiconductor device according to an embodiment of the present disclosure.

FIGS. 10A, 10B, 10C, 11A, 11B, 11C, 12A, 12B, 12C, 13A, 13B, 13C, 13D, 14A, 14B, and 14C illustrate a semiconductor device formed utilizing a method of manufacturing a semiconductor device according to an embodiment of the present disclosure.

FIGS. 15A, 15B, 16A, 16B, 17A, 17B, and 17C illustrate a semiconductor device formed utilizing a method of manufacturing a semiconductor device according to an embodiment of the present disclosure.

FIGS. 18A, 18B, 19A, 19B, 20A, 20B, 20C, 21A, 21B, and 21C illustrate a semiconductor device formed utilizing a method of manufacturing a semiconductor device according to an embodiment of the present disclosure.

FIG. 22 is a drawing illustrating a semiconductor device according to an embodiment of the present disclosure.

FIG. 23 is a drawing illustrating a semiconductor device according to an embodiment of the present disclosure.

The drawings are not necessarily drawn to scale and include differing quantities of various structures between the cross-sectional views and corresponding plan views, and complete versions of some structures are not shown between the cross-sectional views and corresponding plan views.

### DETAILED DESCRIPTION

An embodiment of the present disclosure provides a semiconductor device and a method of manufacturing the semiconductor device having a stable structure and an improved characteristic.

According to the present disclosure, a semiconductor device having a stable structure and improved reliability may be provided.

Embodiments of the present disclosure are described with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification. Common or overlapping subject matter is not repeated.

Terms such as “horizontal,” “top,” “bottom,” “under,” “over,” “on,” “side,” “lower,” “lowermost,” “level,” and other terms implying relative spatial relationship or orientation are utilized only for the purpose of ease of description or reference to a drawing and are not otherwise limiting. When one element is identified as “connected” to another element, the elements may be connected directly or through at least one intervening element between the elements. When two elements are identified as “directly connected,” one element is directly connected to the other element without an intervening element between the two elements.

The cross-hatching throughout the figures illustrates corresponding or similar areas between the figures rather than indicating the materials associated with the areas.

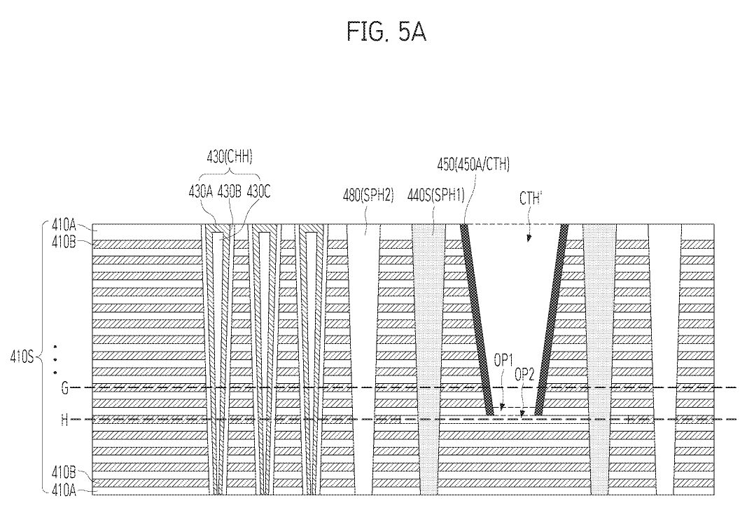

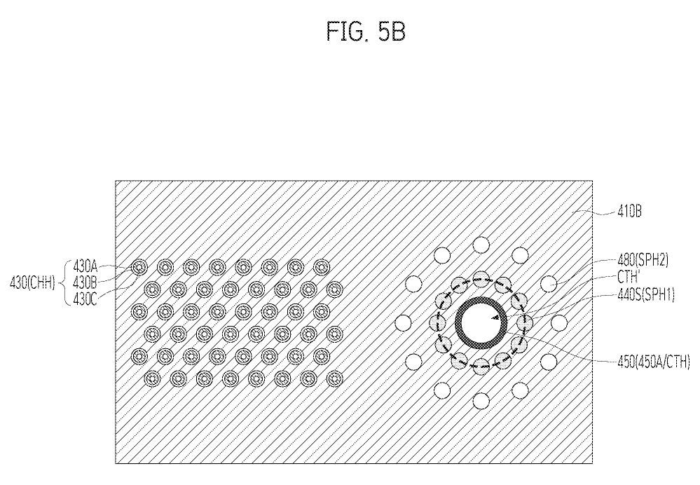

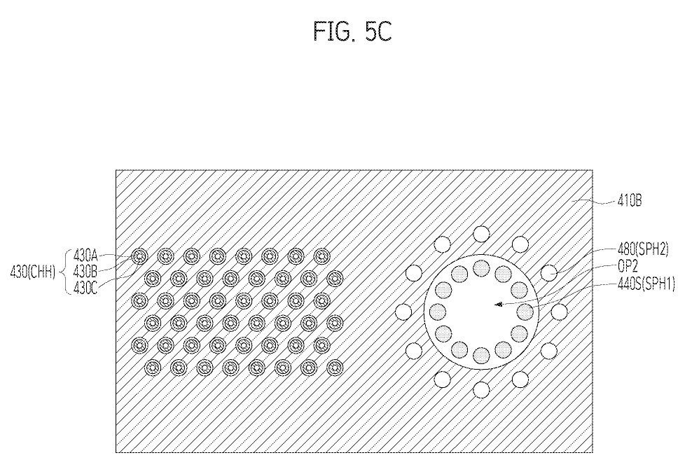

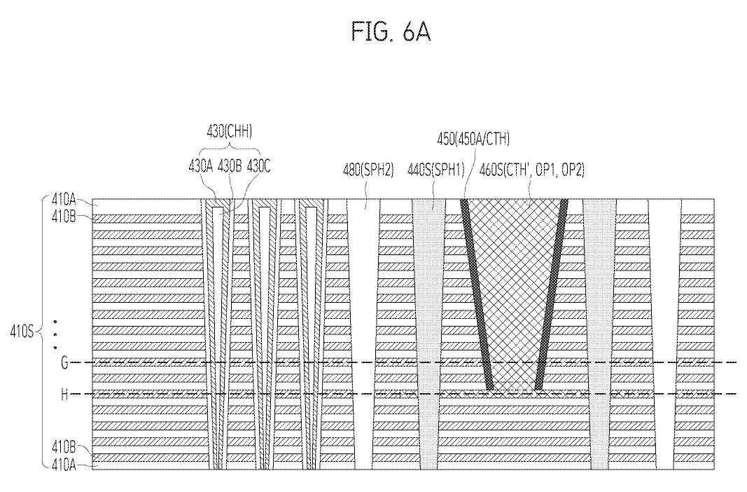

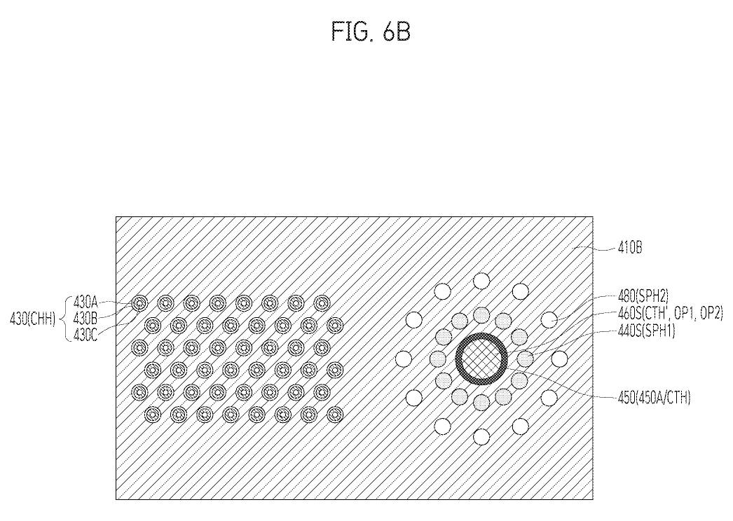

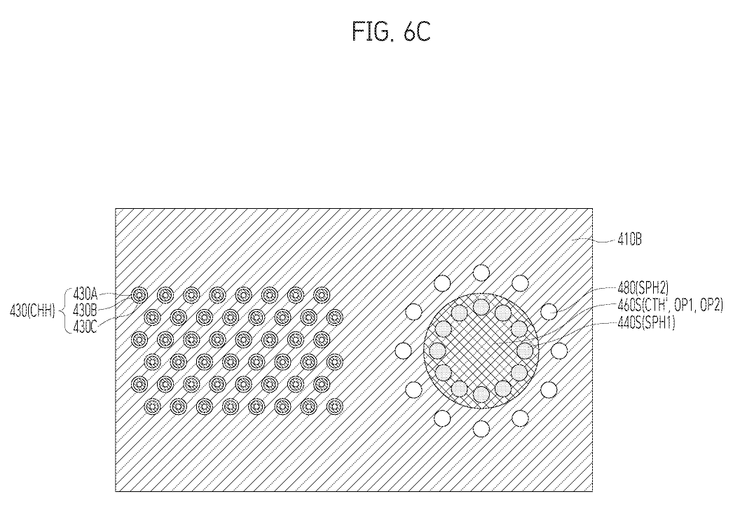

The drawings include reference numerals/names that indicate an object and, within parentheses next to the reference numeral/name, one or more features, elements, sacrificial materials, or holes utilized during the process of forming the object. For example, the lead line for 440S(SPH1) indicates sacrificial layers 440S formed within first support holes SPH1, such as shown in FIG. 5A. The lead line for 450(450A/CTH) indicates the contact spacer 450 formed from the preliminary contact spacer 450A that is formed within the contact hole CTH, such as shown in FIGS. 6A and 6B. The lead line for 460S(CTH,OP1,OP2) indicates the contact sacrificial layer 460S formed within the contact hole CTH, the first opening OP1, and the second opening OP2, such as shown in FIGS. 6A, 6B and 6C.

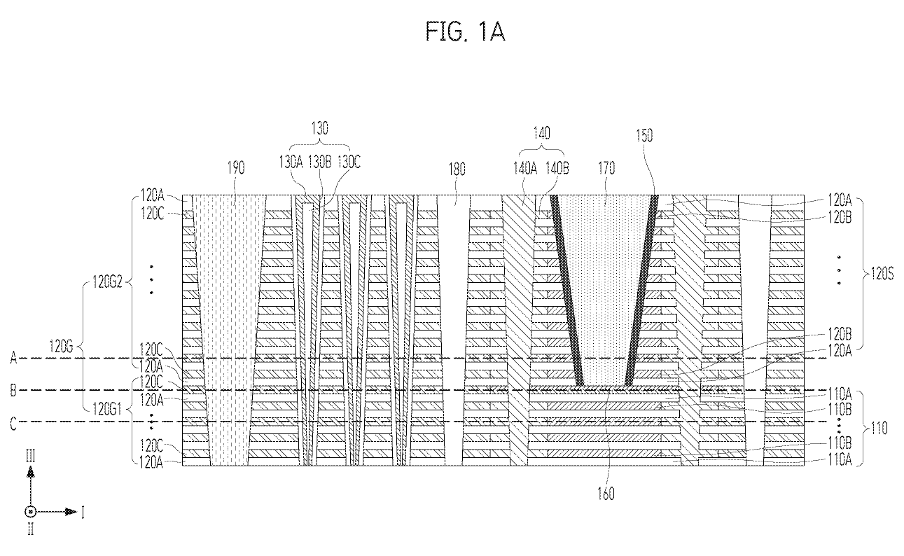

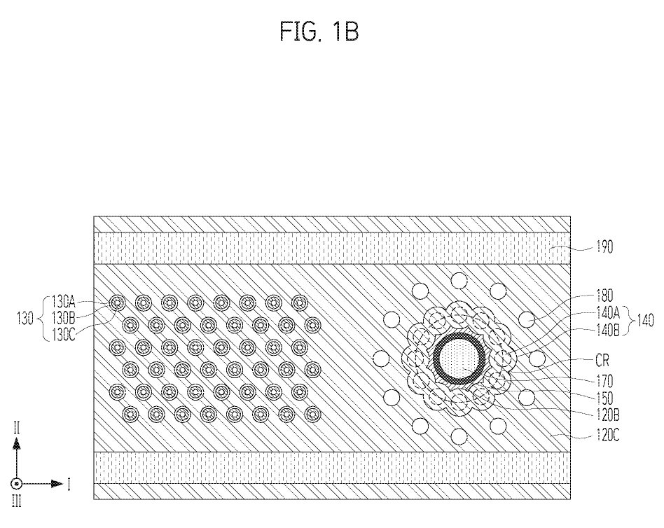

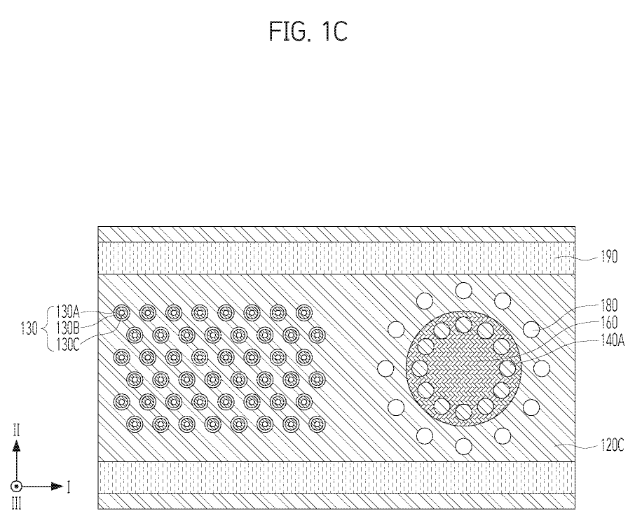

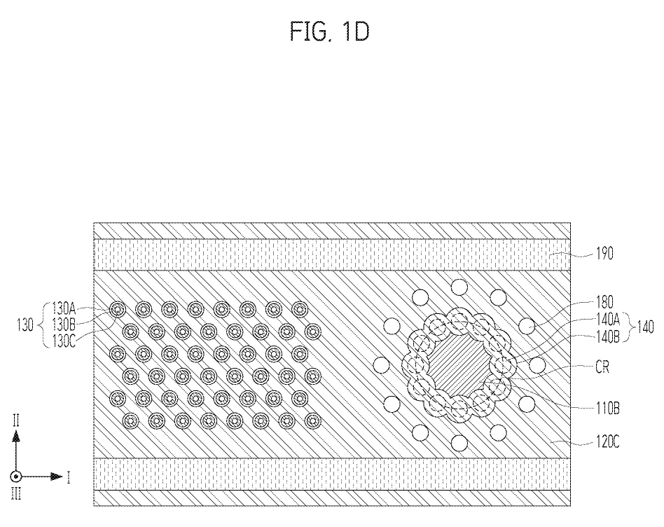

FIGS. 1A,1B, 1C, and 1D illustrate a semiconductor device according to an embodiment of the present disclosure. FIG. 1A is a cross-sectional view, FIG. 1B is a plan view at level A of FIGS. 1A, 1C is a plan view at level B of FIGS. 1A, and 1D is a plan view at level C of FIG. 1A.

Referring to FIGS. 1A to 1D, the semiconductor device includes a support structure 110, a stack 120S, a gate structure 120G, channel structures 130, separation structures 140, a contact spacer 150, a contact pattern 160, a contact plug 170, supports 180, and slit structures 190.

The support structure 110 include first insulating layers 110A alternately stacked with second insulating layers 110B. The support structure 110 supports the semiconductor device during a process of forming the gate structure 120G. The first insulating layers 110A and the second insulating layers 110B may include different materials. For example, the first insulating layers 110A may include an insulating material such as an oxide, and the second insulating layers 110B may include an insulating material such as a nitride.

The stack 120S is located on the support structure 110. The stack 120S includes first insulating layers 120A alternately stacked with second insulating layers 120B. The insulating layers 120A and 120B correspond to the second insulating layers 110A and 110B of the support structure 110. The first insulating layers 120A may include an insulating material such as an oxide, and the second insulating layers 120B may include an insulating material such as a nitride.

The gate structure 120G surrounds the stack 120S. For example, the gate structure 120G surrounds the stack 120S and the support structure 110. The gate structure 120G includes first insulating layers 120A alternately stacked with conductive layers 120C. The gate structure 120G includes a first section 120G1 located at levels corresponding to the levels of the support structure 110 and a second section 120G2 located at levels corresponding to the levels of the stack 120S.

The conductive layers 120C are gate lines such as a source selection line, a word line, and a drain selection line. A source selection transistor, a memory cell, or a drain selection transistor are located in a region where the channel structures 130 and the conductive layers 120C intersect. For example, one memory string includes at least one source selection transistor, a plurality of memory cells, and at least one drain selection transistor stacked along the channel structure 130. The first insulating layers 120A may include an insulating material such as an oxide. The conductive layers 120C may include a conductive material such as tungsten, molybdenum, or polysilicon. The conductive layers 120C may include metal nitride. For example, the conductive layers 120C may include at least one of titanium nitride TiN or tantalum nitride TaN.

The channel structures 130 extend through the gate structure 120G. Each of the channel structures 130 includes a channel layer 130A and a memory layer 130B surrounding the channel layer 130A. Each of the channel structures 130 includes an insulating core 130C surrounded by the channel layer 130A. The channel layer 130A may include a semiconductor material such as polysilicon or germanium. The insulating core 130C may include an insulating material such as an oxide.

The contact plug 170 is located on the support structure 110. In other words, the support structure 110 is located under the contact plug 170. The contact plug 170 extends through the stack 120S. The contact plug 170 is connected to one of the conductive layers 120C of the gate structure 120G. The conductive layer 120C connected to the contact plug 170 is referred to as a first conductive layer. The contact plug 170 may include a conductive material such as tungsten.

The contact spacer 150 surrounds a sidewall of the contact plug 170. The contact spacer 150 insulates the contact plug 170 and the conductive layers 120C except for the first conductive layer electrically connected to the contact plug 170. The contact spacer 150 may include an insulating material such as an oxide.

The separation structures 140 extend through the stack 120S and the gate structure 120G. For example, the separation structures 140 extend through the stack 120S and the gate structure 120G and extend through the support structure 110 and the gate structure 120G. The separation structure 140 separates the gate structure 120G from the stack 120S. For example, the separation structure 140 separates a region where the support structure 110 and the stack 120S are located from a region where the gate structure 120G is located. In other words, the separation structure 140 separates a region where the contact plug 170 is located from a region where the gate structure 120G is located.

The separation structure 140 includes pillars 140A arranged around the contact plug 170 and a plurality of extensions 140B, each extension 140B located at a level corresponding to a level of a conductive layer 120C except for the first conductive layer. The plurality of extensions 140B interconnects the pillars 140A. The extensions 140B are interconnected or joined in a plane to form a closed region CR within the plane. The support structure 110 and the stack 120S are located within the closed region CR. The second insulating layers 110B of the support structure 110 and the second insulating layers 120B of the stack 120S are located at levels corresponding to levels of the extensions 140B. The separation structure 140 may include an insulating material such as an oxide.

The contact pattern 160 is located between the support structure 110 and the stack 120S. The contact pattern 160 extends around the separation structures 140. For example, the contact pattern 160 extends between the pillars 140A. The contact pattern 160 electrically connects the contact plug 170 and the first conductive layer among the conductive layers 120C. The contact pattern 160 is integral with or connected to the contact plug 170. Although a boundary or surface between the contact pattern 160 and the contact plug 170 is shown in FIG. 1A, a boundary or surface may not exist between the contact pattern 160 and the contact plug 170. The contact pattern 160 may include a conductive material such as tungsten.

According to an embodiment of the present disclosure, the contact pattern 160 extends around the separation structure 140 (not shown) and electrically connects the first conductive layer and the contact plug 170. In other words, the contact pattern 160 extends in a horizontal direction through or around the separation structure 140 and electrically connects the contact plug 170 and the first conductive layer. The contact pattern 160 may include a material substantially similar to a material included in the contact plug 170.

According to an embodiment of the present disclosure, the contact pattern 160 and the contact plug 170 may be separate structures. In this example, an interface exists between the contact pattern 160 and the contact plug 170. The contact pattern 160 and the contact plug 170 may include different materials. For example, the contact pattern 160 may include tungsten, and the contact plug 170 may include polysilicon.

The supports 180 extend through the gate structure 120G. The supports 180 are spaced apart from the separation structure 140. The supports 180 may have a structure similar to the channel structures 130. For example, each of the supports 180 includes at least one of a dummy channel layer, a dummy memory layer surrounding the dummy channel layer, and a dummy insulating core surrounded by the dummy channel layer. The supports 180 may include an insulating material such as an oxide. Alternatively, the supports 180 may include a conductive layer such as tungsten and an insulating layer surrounding the conductive layer.

The slit structure 190 extends through the gate structure 120G. The term “slit structure” does not indicate that the structure is a slit but rather is so named because the process of forming the slit structure utilizes a slit. A slit structure may be referred to as a divider. The slit structure 190 may include an insulating material, a conductive material, or a semiconductor material.

According to the structure described with respect to FIGS. 1A to 1D, the separation structure 140 separates the region where the contact plug 170 is located and the region where the gate structure 120G is located. The contact pattern 160 extends in a horizontal direction through or around the separation structure 140, and electrically connects the contact plug 170 with the first conductive layer among the conductive layers 120C of the gate structure 120G.

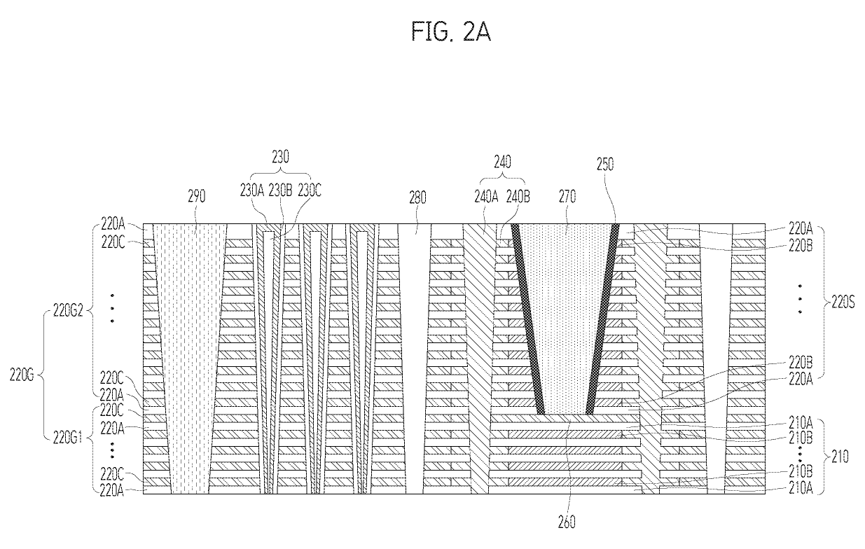

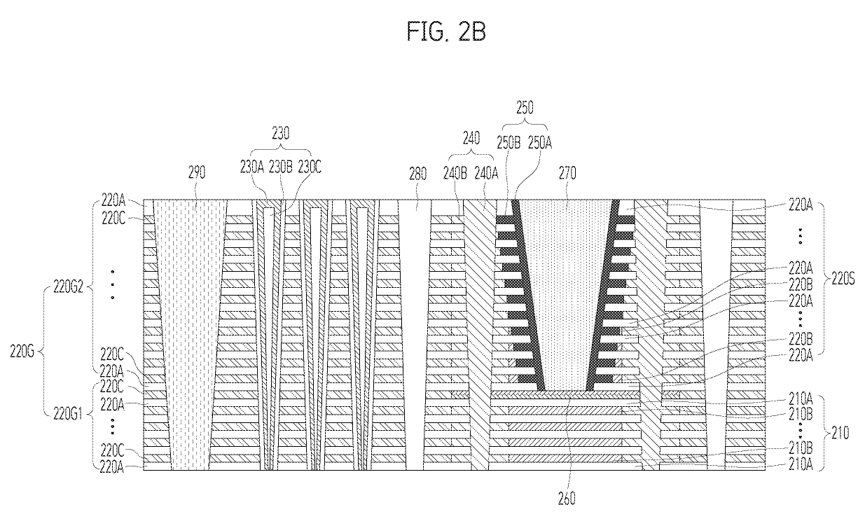

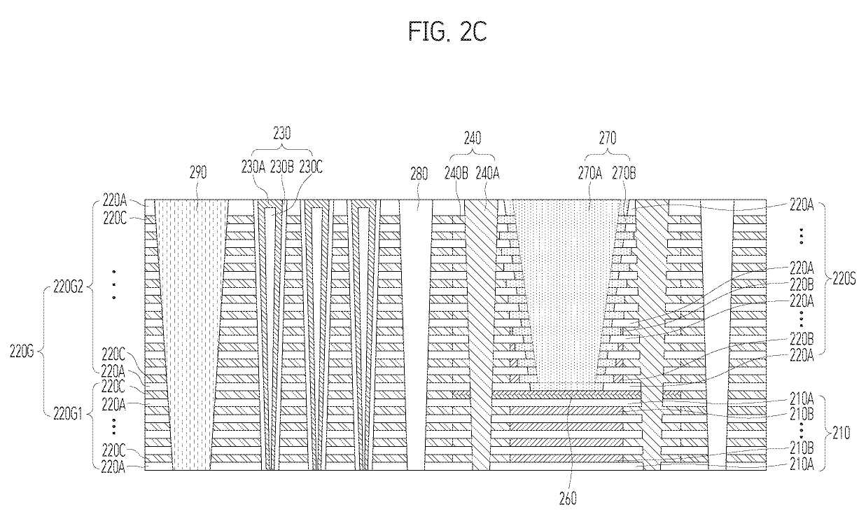

FIGS. 2A, 2B, and 2C illustrate a semiconductor device according to an embodiment of the present disclosure. For the sake of brevity, content described for one figure and applicable to subsequent figures is not repeated for each figure throughout the specification.

Referring to FIGS. 2A, 2B and 2C, the semiconductor device includes a support structure 210, a stack 220S, a gate structure 220G, channel structures 230, separation structures 240, a contact spacer 250, a contact pattern 260, a contact plug 270, supports 280, and slit structures 290.

The support structure 210 includes first insulating layers 210A alternately stacked with second insulating layers 210B. The first insulating layers 210A may include an insulating material such as an oxide, and the second insulating layers 210B may include an insulating material such as a nitride.

The stack 220S may be located on the support structure 210. The stack 220S includes first insulating layers 220A alternately stacked with second insulating layers 220B. The insulating layers 220A and 220B correspond to the insulating layers 210A and 210B of the support structure 210. The first insulating layers 220A may include an insulating material such as an oxide, and the second insulating layers 220B may include an insulating material such as a nitride.

The gate structure 220G surrounds the stack 220S. For example, the gate structure 220G surrounds the stack 220S and the support structure 210. The gate structure 220G includes first insulating layers 220A alternately stacked with conductive layers 220C. The gate structure 220G includes a first section 220G1 located at levels corresponding to the levels of the support structure 210 and a second section 220G2 located at levels corresponding to the stack 220S.

The channel structures 230 extends through the gate structure 220G. Each of the channel structures 230 includes a channel layer 230A, a memory layer 230B surrounding the channel layer 230A, and an insulating core 230C surrounded by the channel layer 230A.

The contact plug 270 is located on the support structure 210. The contact plug 270 extends through the stack 220S and is connected to one of the conductive layers 220C of the gate structure 220G. The conductive layer 220C connected to the contact plug 270 is referred to as a first conductive layer. Referring to FIG. 2C, the contact plug 270 includes body 270A and protrusions 270B protruding or extending from the body 270A.

The contact spacer 250 surrounds a sidewall of the contact plug 270. The contact spacer 250 insulates the contact plug 270 and the conductive layers 220C except for the first conductive layer electrically connected to the contact plug 270. Referring to FIG. 2C, the contact spacer 250 is not included in an embodiment. For example, because the contact plug 270 is insulated from the conductive layers 220C by the separation structure 240, the contact spacer 250 is not included.

The separation structure 240 extends through the stack 220S and the gate structure 220G. The separation structure 240 separates the gate structure 220G from the stack 220S. For example, the separation structure 240 separates a region where the contact plug 270 is located from a region where the gate structure 220G is located. The separation structure 240 includes pillars 240A arranged around the contact plug 270 and a plurality of extensions 240B, each extension 240B located at a level corresponding to the conductive layers 220C except for the first conductive layer. The plurality of extensions 240B interconnects the pillars 240A.

The contact pattern 260 is located between the support structure 210 and the stack 220S. The contact pattern 260 extend around the separation structure 240. For example, the contact pattern 260 extends between the pillars 240A. The contact pattern 260 electrically connects the contact plug 270 with the first conductive layer among the conductive layers 220C.

The supports 280 extend through the gate structure 220G. The supports 280 may have a structure similar to the channel structures 230. The supports 280 may include an insulating material such as an oxide. The supports 280 may include a conductive layer such as tungsten and an insulating layer surrounding the conductive layer. The slit structure 290 extends through the gate structure 220G. The slit structure 290 may include an insulating material, a conductive material, or a semiconductor material.

According to the structure described with respect to FIGS. 2A and 2B, the contact pattern 260 is integral with or connected to the first conductive layer connected to the contact plug 270 among the conductive layers 220C. The first conductive layer extends through or around the separation structures 240 and is electrically connected to the contact plug 270.

The contact spacer 250 includes a body 250A and protrusions 250B protruding or extending from the body 250A. The protrusions 250B extend in a horizontal direction relative to the drawing and insulate the contact plug 270 from the conductive layers 220C by establishing a margin between the contact plug 270 and the conductive layers 220C in the horizontal direction.

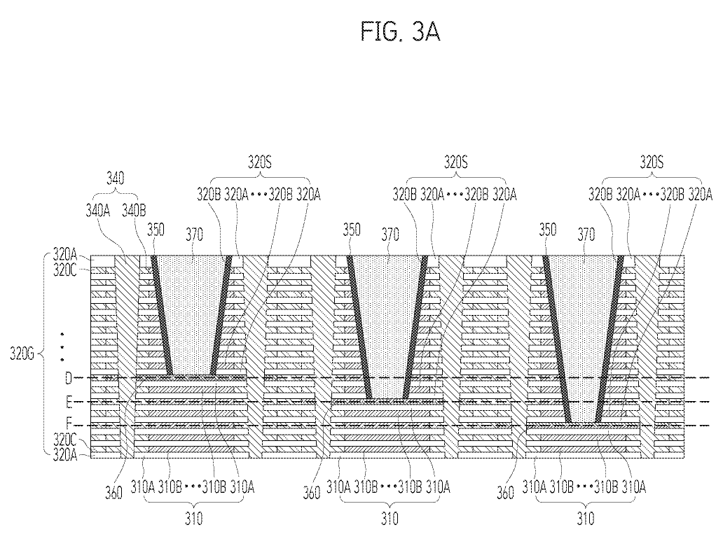

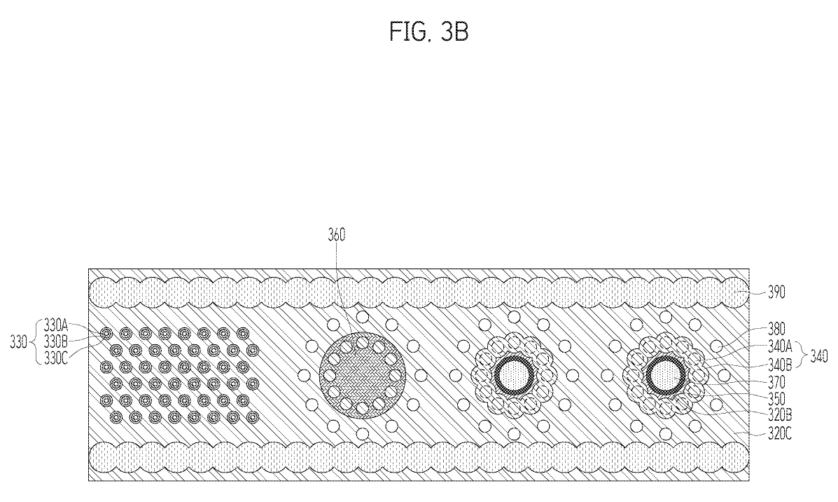

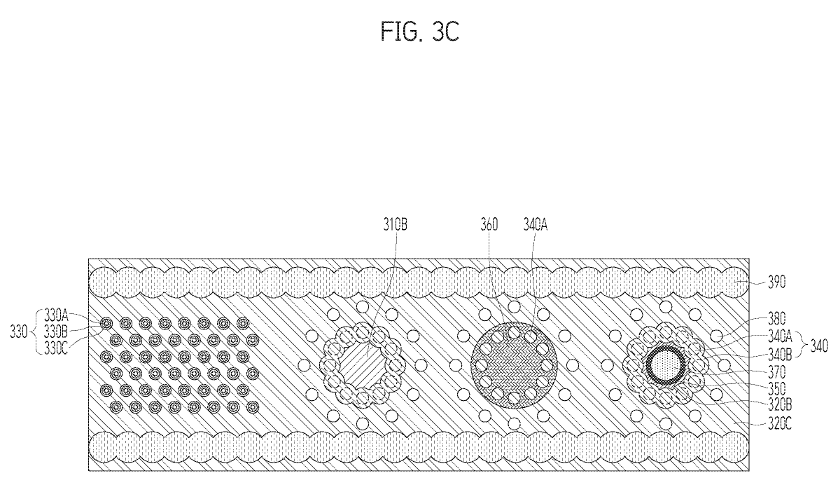

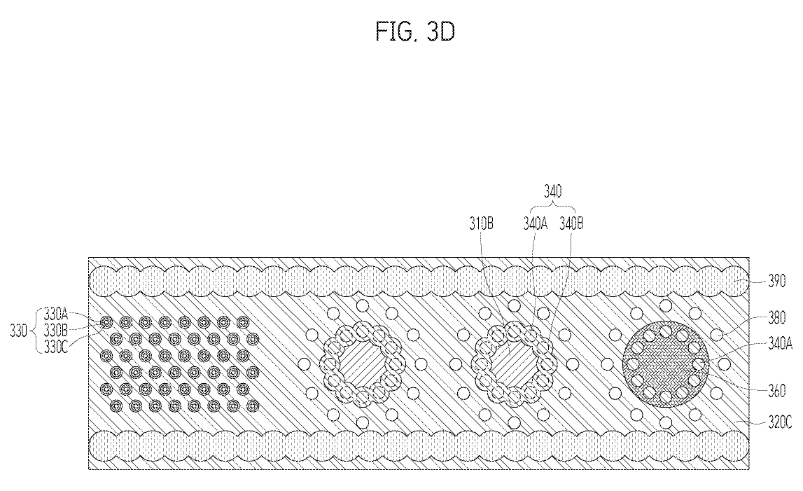

FIGS. 3A, 3B, 3C, and 3D illustrate a semiconductor device according to an embodiment of the present disclosure. FIG. 3A is a cross-sectional view, FIG. 3B is a plan view at level D of FIGS. 3A, 3C, is a plan view at level E of FIGS. 3A, and 3D, is a plan view at level F of FIG. 3A.

Referring to FIGS. 3A to 3D, the semiconductor device includes a support structures 310, a gate structure 320G, stacks 320S, channel structures 330, separation structures 340, contact spacers 350, contact patterns 360, contact plugs 370, supports 380, and slit structures 390.

Each of the support structures 310 include first insulating layers 310A alternately stacked with second insulating layers 310B. Each support structure 310 has a different height. For example, each of the support structures 310 includes a different quantity of insulating layers 310A alternately stacked with insulating layers 310B.

The stacks 320S are located on corresponding support structures 310. Each of the stacks 320S includes first insulating layers 320A insulating layers second insulating layers 320B. Each stack 320S has a different height. The stacks 320S may have a height inversely proportional to a corresponding support structures 310. For example, the support structure 310 having a relatively large height corresponds to the stack 320S having a relatively small height.

The gate structure 320G surrounds the support structures 310 and the stacks 320S. The gate structure 320G includes first insulating layers 320A insulating layers conductive layers 320C.

Each of the contact plugs 370 extends through a corresponding stack 320S and is connected to one of the conductive layers 320C of the gate structure 320G. Each of the contact plugs 370 is located on a corresponding support structures 310. For example, the contact plugs 370 may be located in a region corresponding to the support structures 310, respectively. The quantity of the contact plugs 370 is equal to the quantity of the support structures 310. The contact plugs 370 have different heights. Each of the contact plugs 370 may have a height inversely proportional to a corresponding support structure 310 and a height proportional to a corresponding stack 320S. For example, when the height of the contact plug 370 is small, the height of the corresponding support structure 310 is large, and the height of the corresponding stack 320S is small. Because the gate structure 320G has a constant height, the height of a contact plug 270, that has the same height as a corresponding stack 320S, plus the height of the corresponding support structure 310 is the same as the height of the gate structure 320G.

Each of the contact spacers 350 surrounds a sidewall of a corresponding contact plug 370. The contact spacers 350 insulate the contact plug 370 and conductive layers 320C except for the conductive layer 320C electrically connected to the contact plug 370.

Each of the separation structures 340 is located between a corresponding stack 320S and the gate structure 320G. Each separation structure 340 separates a region where a corresponding contact plug 370 is located from a region where the gate structure 320G is located. The separation structure 340 includes pillars 340A arranged around the contact plug 370 and extensions 340B protruding from the pillars 340A in a horizontal direction.

Each of the contact patterns 360 is located between a corresponding support structure 310 and a corresponding stack 320S. The contact patterns 360 extend through or around the separation structures 340. The contact patterns 360 electrically connect the conductive layers 320C and corresponding contact plugs 370. The contact pattern 360 is integral with or connected to the contact plug 370. For example, the contact pattern 360 is integral with the first conductive layer among the conductive layers 320C and is connected to the contact plug 370.

According to the structure described with respect to FIGS. 3A to 3D, the contact plugs 370 are located on corresponding support structures 310. For example, the contact plugs 370 are located in a region corresponding to the support structures 310. The quantity of the contact plugs 370 is equal to the quantity of the support structures 310. The support structures 310 have different heights corresponding to contact plugs 370 having different heights, thereby improving support or supporting force under the contact plugs 370.

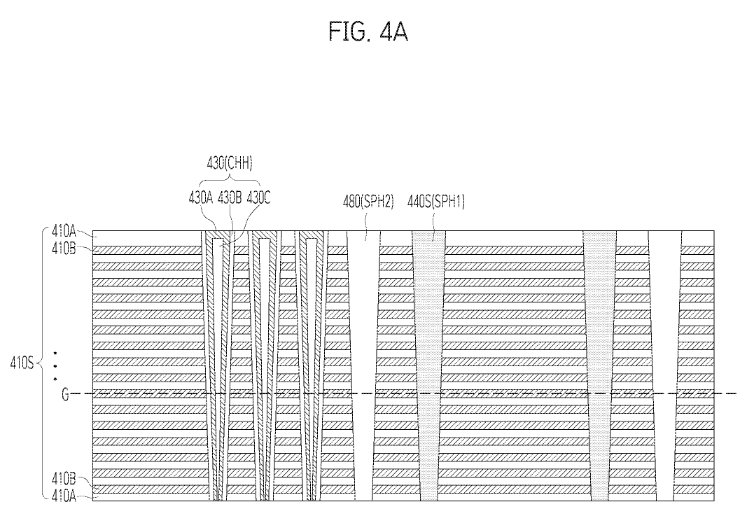

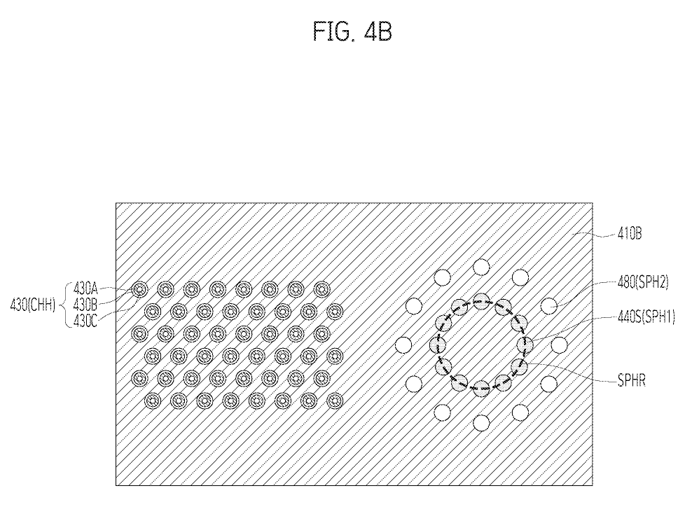

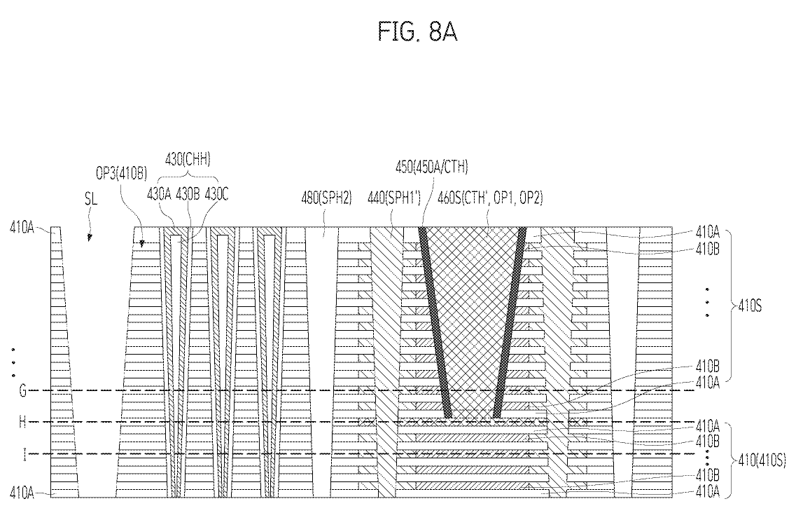

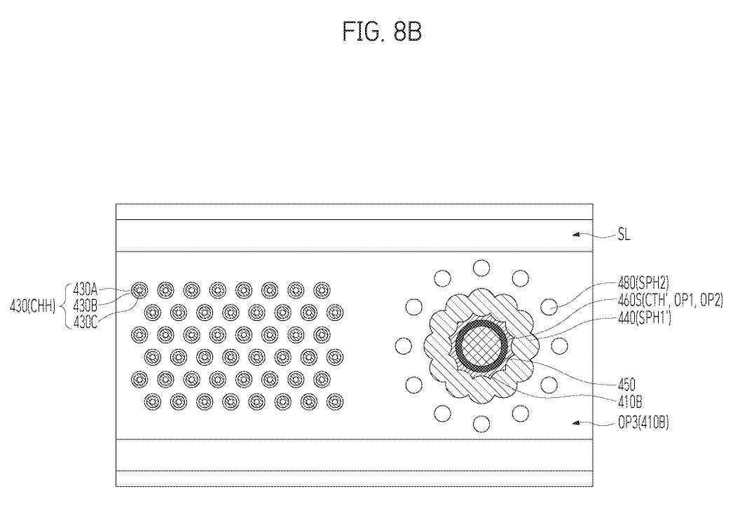

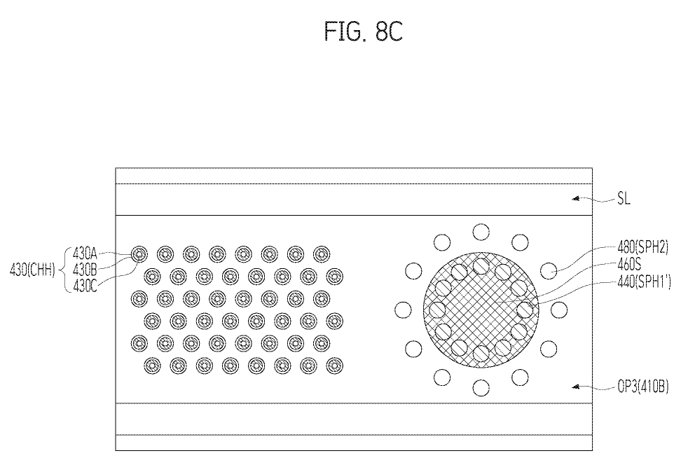

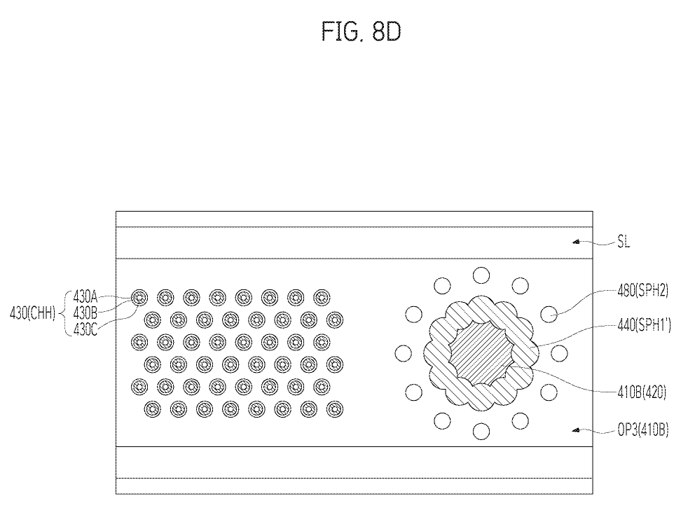

FIGS. 4A, 4B, 5A, 5B, 5C, 6A, 6B, 6C, 7A, 7B, 7C, 8A, 8B, 8C, 8D, 9A, 9B, and 9C illustrate a semiconductor device formed utilizing a method of manufacturing a semiconductor device according to an embodiment of the present disclosure. FIGS. 4A, 5A, 6A, 7A, 8A and 9A are cross-sectional views, FIGS. 4B, 5B, 6B, 7B, 8B and 9B are plan views at level G of FIGS. 4A, 5A, 6A, 7A, 8A and 9A, respectively, FIGS. 5C, 6C, 7C, 8C and 9C are plan views at level H of FIGS. 5A, 6A, 7A, 8A and 9A, respectively, and FIG. 8D is a plan view at level I of FIG. 8A.

Referring to FIGS. 4A and 4B, a stack 410S is formed by alternately stacking first material layers 410A with second material layers 410B. The first material layers 410A and the second material layers 410B may include different materials. For example, the first material layers 410A may include an insulating material such as an oxide, and the second material layers 410B may include a material such as a nitride.

Channel holes CHH are formed extending through the stack 410S. First support holes SPH1, referred as first holes, are formed extending through the stack 410S. Second support holes SPH2, referred as second holes, are formed extending through the stack 410S. The term “support hole” does not indicate that a support hole provides physical support but rather is so named because the process of forming a support or other supporting structure utilizes the support hole. The first support holes SPH1 and/or the second support holes SPH2 may be formed while the channel holes CHH are formed. The present disclosure is not limited to this example, and the channel holes CHH, the first support holes SPH1 and/or the second support holes SPH2 may be formed at different times.

The first support holes SPH1 are formed in a region where a contact hole is formed in a subsequent process. The region where the contact hole is formed is a region SPHR delineated by the first support holes SPH1. The second support holes SPH2 are formed around the first support holes SPH1.

A channel structure 430 is formed in each of the channel holes CHH. Each of the channel structures 430 includes a channel layer 430A, a memory layer 430B surrounding the channel layer 430A, and an insulating core 430C surrounded by the channel layer 430A.

A supports 480 is formed in each of the second support holes SPH2. The supports 480 may be formed while the channel structures 430 are formed. In this example, the supports 480 have a structure similar to the channel structures 430. For example, each of the supports 480 includes at least one of a dummy channel layer, a dummy memory layer surrounding the dummy channel layer, and a dummy insulating core surrounded by the dummy channel layer. The present disclosure is not limited to this example, and the supports 480 may be formed at a time different from a time when the channel structures 430 are formed. In this example, the supports 480 may include an insulating material such as an oxide. Alternatively, the supports 480 may include a conductive layer such as tungsten and an insulating layer covering the conductive layer.

Support sacrificial layers 440S are formed in the first support holes SPH1. The support sacrificial layers 440S may include a material such as carbon or polysilicon.

Referring to FIGS. 5A to 5C, a contact hole CTH extending through the stack 410S is formed. For example, the contact hole CTH is formed within the region SPHR delineated by the first support holes SPH1 and extends through the stack 410S. One of the first material layers 410A is exposed through the contact hole CTH.

A preliminary contact spacer 450A is formed in the contact hole CTH. For example, the preliminary contact spacer 450A is conformally formed adjacent to the stack 410S within the contact hole CTH. The preliminary contact spacer 450A may include an insulating material such as an oxide.

A first opening OP1 is formed, for example, by etching a lowermost surface of the preliminary contact spacer 450A, the second material layer 410B is exposed through the first opening OP1, and the auxiliary contact hole CTH’ within the resulting contact spacer 450. The contact spacer 450 of a contact plug may be formed by etching the lowermost surface of the preliminary contact spacer 450A.

A second opening OP2 is formed by selectively removing the second material layer 410B through the first opening OP1. For example, the second opening OP2 is formed by selectively removing the second material layer 410B such that the support sacrificial layers 440S are exposed through the first opening OP1.

Referring to FIGS. 6A to 6C, a contact sacrificial layer 460S is formed within the second opening OP2, within the first opening OP1, and within the spacer 450 that is formed in the contact hole CTH. For example, the contact sacrificial layer 460S is formed to fill the second opening OP2, the first opening OP1, and the spacer 450 that is formed in the contact hole CTH. The contact sacrificial layer 460S may include a material such as carbon or polysilicon.

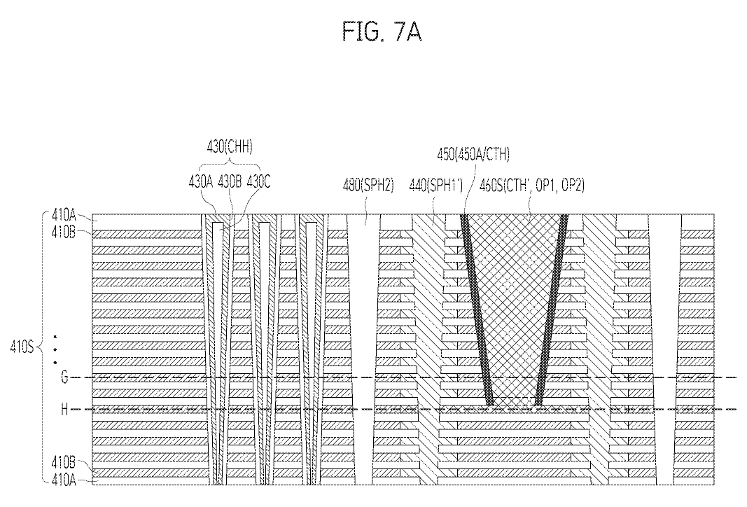

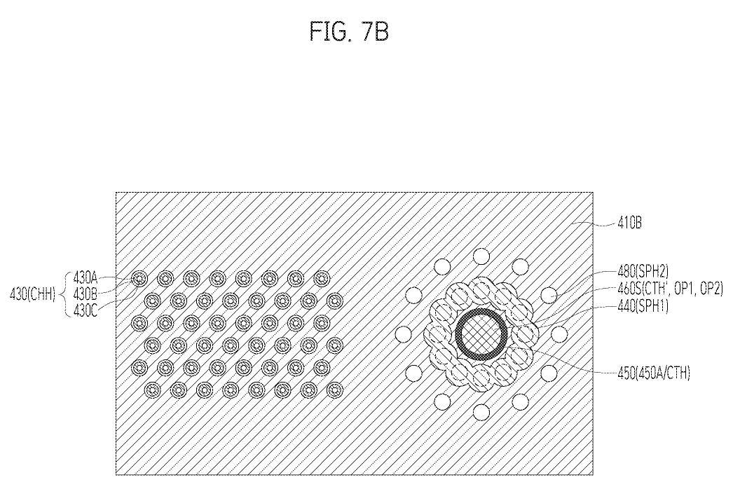

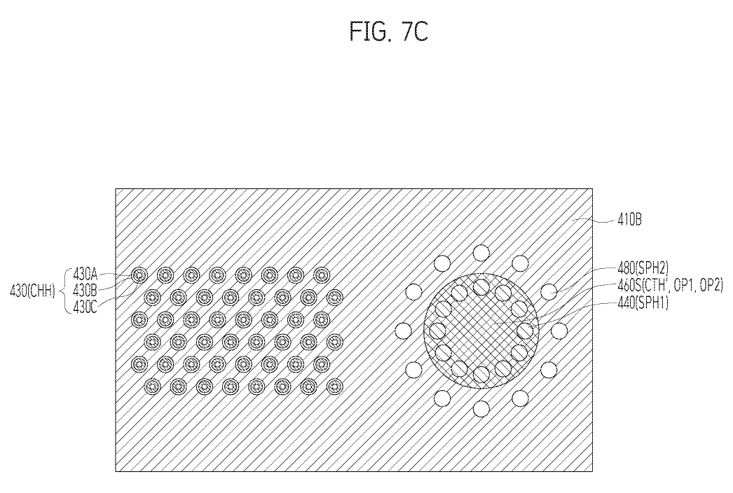

Referring to FIGS. 7A to 7C, the support sacrificial layers 440S are removed, resulting in auxiliary first support holes SPH1’. The auxiliary first support holes SPH1’ are expanded by selectively removing the second material layers 410B through the auxiliary first support holes SPH1’. For example, the auxiliary first support holes SPH1’ are expanded such that the auxiliary first support holes SPH1’ are contiguous, adjoining, or interconnected. In this example, the auxiliary first support holes SPH1’ are expanded to form a single contiguous auxiliary support hole. In the example shown in the drawings, the contiguous auxiliary support hole is generally ring-shaped, with a chain of expanded holes distributed evenly around the ring.

A separation structure 440 is formed in the contiguous auxiliary support hole. In this example, the separation structure 440 forms a closed region within the region SPHR delineated by the contiguous auxiliary support hole. The separation structure 440 separates a region where the contact hole CTH is formed in a region where a gate structure is located. The separation structure 440 may include an insulating material such as an oxide.

Referring to FIGS. 8A to 8D, a slit SL is formed extending through the stack 410S. The slit SL may have a rectangular shape, where two sides of the rectangle are shown horizontally in the plan views of FIGS. 8B, 8C, and 8D and another side of the rectangle is shown vertically in the cross-sectional view of FIG. 8A. Third openings OP3 are formed by removing the second material layers 410B through the slit SL. The separation structure 440 is exposed through at least one of the third openings OP3. The contact sacrificial layer 460S is exposed through one of the third openings OP3. In this example, the stack 410S remains in the region where the contact hole CTH is formed by the separation structure 440. The stack 410S located under the contact hole CTH is referred to as a support structure 410.

Although the figures show an example the slit SL formed in a line without protrusion, the shape of the slit SL is not limited to this example. For example, the slit may be formed by forming a plurality of slit holes extending through the stack and subsequently expanding each of the slit holes such that the slit holes merge into a single slit or opening. In this example, the shape of the slit may include protrusions corresponding to the plurality of connected slit holes.

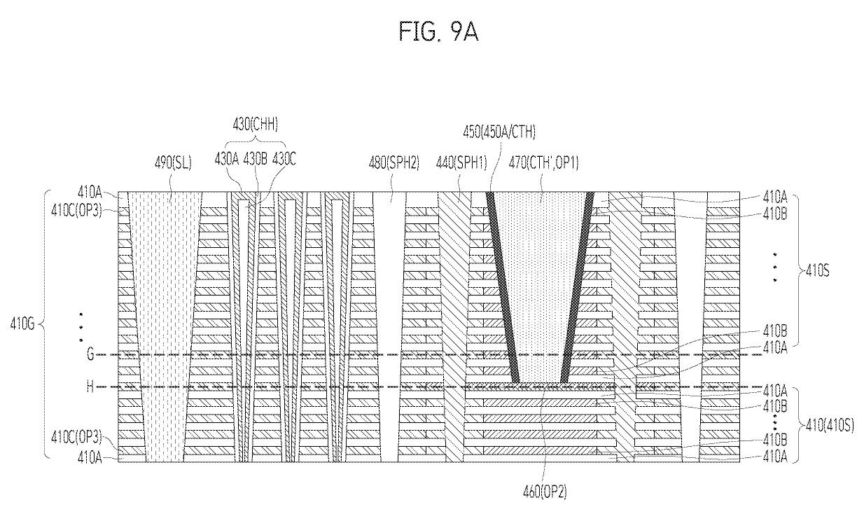

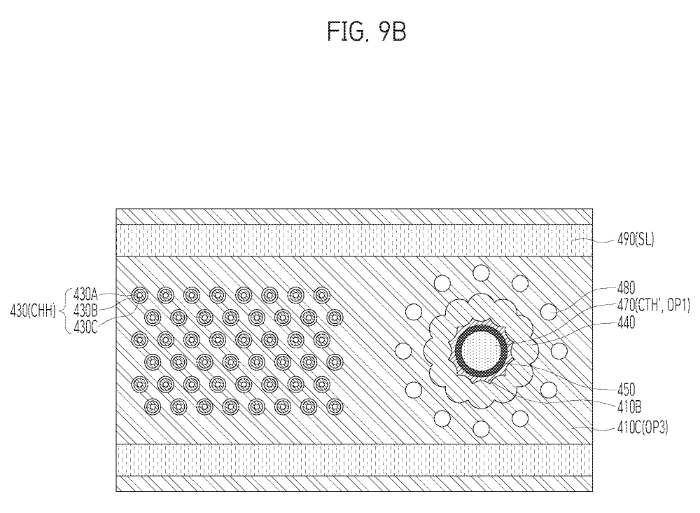

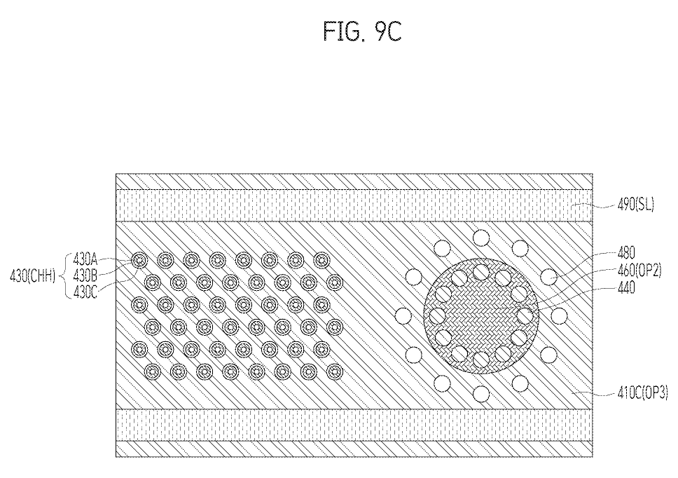

Referring to FIGS. 9A to 9C, third material layers 410C are formed in the third openings OP3. The third material layers 410C are used as gate lines and may include a conductive material such as tungsten. For example, the third material layers 410C may include at least one of tungsten, molybdenum or polysilicon. The third material layers 410C may include metal nitride. For example, the third material layers 410C may include at least one of titanium nitride TiN or tantalum nitride TaN. A gate structure 410G is formed including the first material layers 410A alternately stacked with the third material layers 410C.

Height of the stack may be increased and height of a gate structure may be increased to improve integration density of a semiconductor device. Accordingly, a target height of a contact hole used to form a contact plug connected to the gate line of the gate structure increases, and a width of the contact hole increases. In this example, as a region area where the contact hole is formed increases, a region where supports supporting the stack are formed decreases, thus the stack may bend when removing second material layers during a process of forming the gate structure. Because the supports are not formed under the contact hole, the stack may not be sufficiently supported under the contact hole.

According to an embodiment of the present disclosure, the first support holes SPH1 may be formed in a region where the contact hole CTH is subsequently formed. Because the first support holes SPH1 are formed to form the support structure 420 under the contact hole CTH, the first support holes SPH1 are formed around the contact hole CTH, for example, to surround the contact hole CTH. The separation structure 440 is formed by expanding the auxiliary first support holes SPH1 such that the expanded auxiliary first support holes SPH1 form a single contiguous auxiliary support hole, and the stack 410S remains within the separation structure 440. The stack 410S located under the contact hole CTH is used as the support structure 420. According to an embodiment of the present disclosure, during a process of removing the second material layers 410B to form the gate structure 410G bending of the semiconductor device may be prevented or reduced by use of the separation structure 440, the stack 410S, and the support structure 420.

A slit structure 490 is formed in the slit SL. The slit structure 490 may include at least one of an insulating material, a semiconductor material, and a conductive material.

The auxiliary contact hole CTH’, the first opening OP1, and the second opening OP2 are formed by removing the contact sacrificial layer 460S formed within the spacer 450, the first opening OP1, and the second opening OP2. A conductive material is formed in the auxiliary contact hole CTH’, the first opening OP1, and the second opening OP2. The conductive material may include a conductive material such as tungsten or polysilicon.

A contact pattern 460 is formed in a location of the second opening OP2. A contact plug 470 is formed in a location of the first opening OP1 and the auxiliary contact hole CTH’. In this example, the contact pattern 460 is connected to the third material layer 410C by extending in a horizontal direction around the separation structure 440, and the contact plug 470 is connected to the third material layer 410C through the contact pattern 460.

According to an embodiment of the present disclosure, the stack 410S in which the contact plug 470 is formed and the gate structure 410G are separated by the separation structure 440. In this example, the contact plug 470 and one of the third material layers 410C of the gate structure 410G are connected. According to an embodiment of the present disclosure, the contact pattern 460 extends in the horizontal direction to connected to one of the third material layers 410C, thus the contact plug 470 and the third material layer 410C are electrically connected.

Although the figures show an example including one contact plug 470, the quantity of contact plugs 470 is not limited to this example. For example, the quantity of contact plugs may be equal to the quantity of third material layers 410C. In this example, the contact plugs are connected to the third material layers 410C through corresponding contact patterns and have different heights. A support structure is formed under each contact plug.

According to the described method of manufacturing a semiconductor device, the first support holes SPH1 are formed in the region where the contact hole CTH is subsequently formed, and one contiguous auxiliary support hole is formed by expanding the first support holes SPH1 such that the expanded first support holes SPH1 are contiguous or interconnected. In this example, the stack 410S remains within the region SPHR delineated by the contiguous auxiliary support hole formed from first support holes SPH1, and the stack 410S is used as a support structure that prevents the stack 410S from bending during a process of forming the gate structure 410G.

The separation structure 440 is formed in the contiguous auxiliary support hole. In this example, the stack 410S and the gate structure 410G are separated by the separation structure 440. The contact pattern 460 extends in the horizontal direction around the separation structures 440 to electrically connect the contact plug 470 and one of the third material layers 410C of the gate structure 410G.

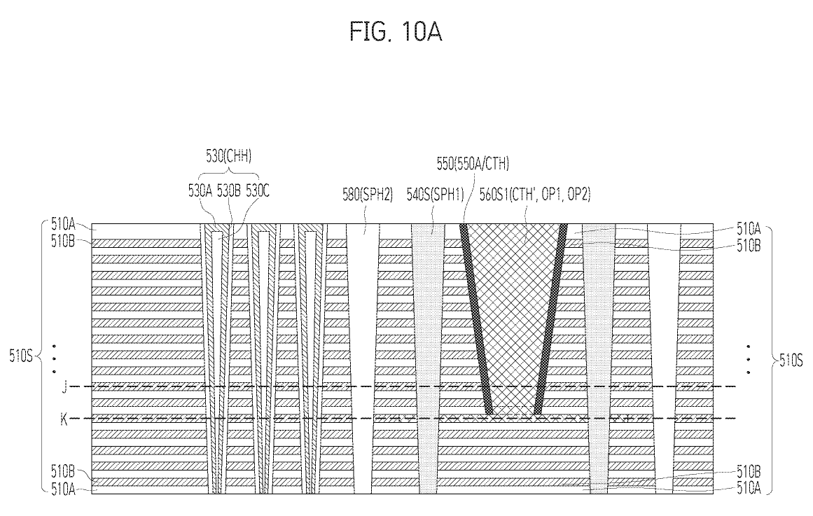

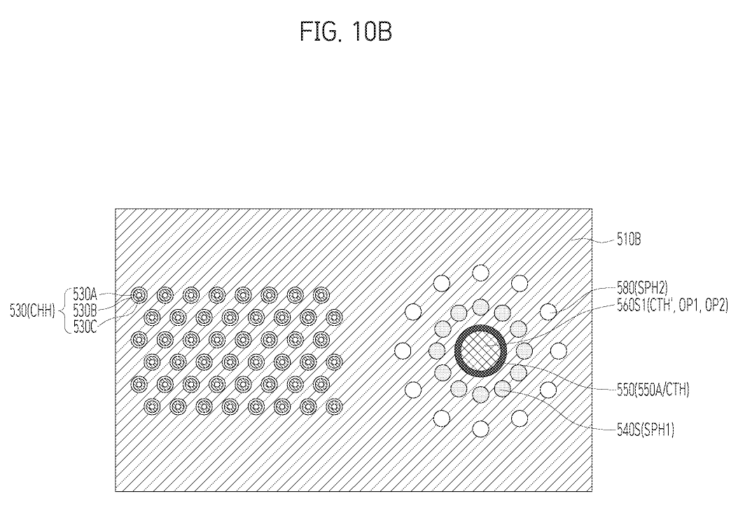

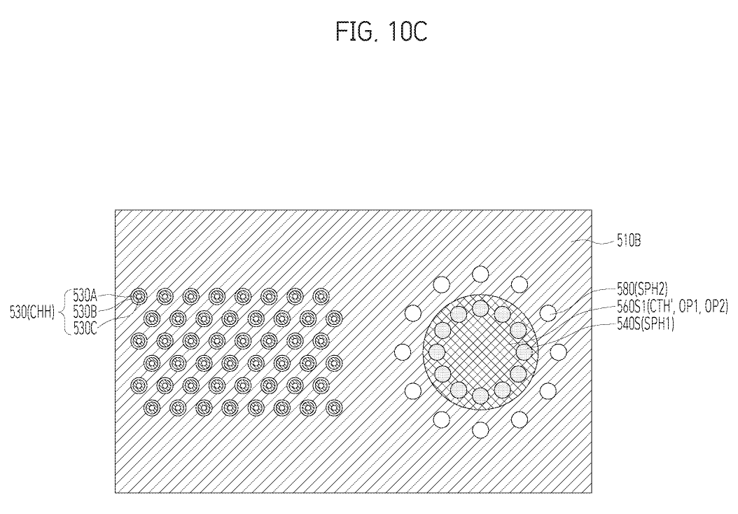

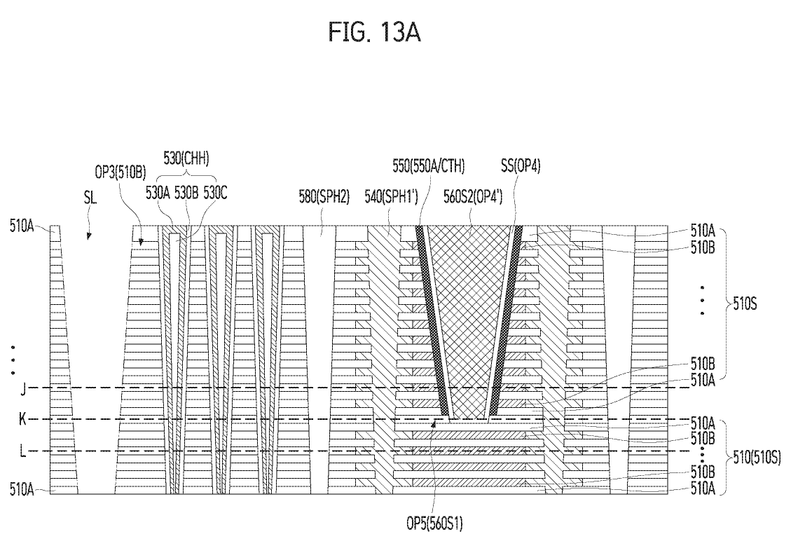

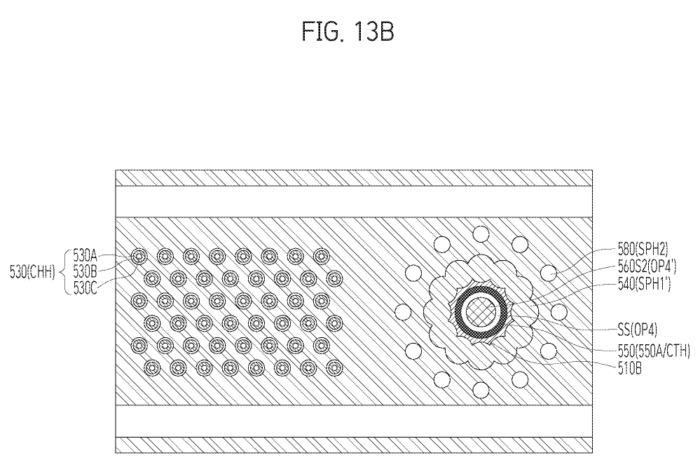

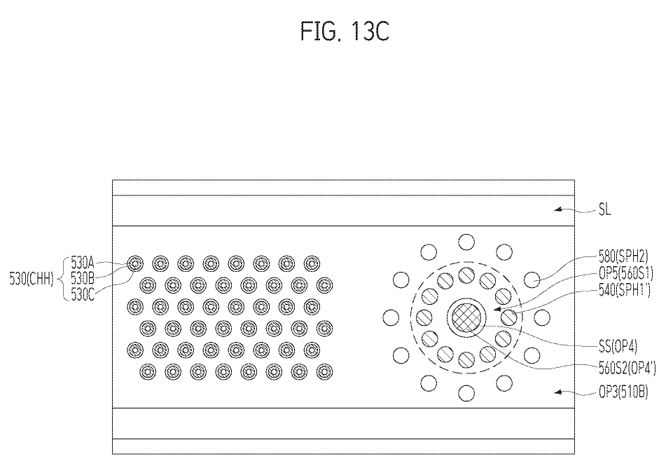

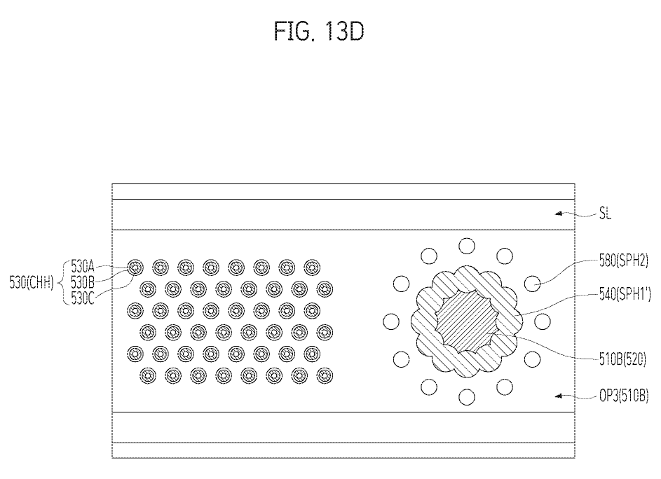

FIGS. 10A, 10B, 10C, 11A, 11B, 11C, 12A, 12B, 12C, 13A, 13B, 13C, 13D, 14A, 14B, and 14C illustrate a semiconductor device formed utilizing a method of manufacturing a semiconductor device according to an embodiment of the present disclosure. FIGS. 10A, 11A, 12A, 13A and 14A are cross-sectional views, FIGS. 10B, 11B, 12B, 13B, and 14B are plan views at level J of FIGS. 10A, 11A, 12A, 13A, and 14A, respectively, and FIGS. 10C, 11C, 12C, 13C, and 14C are plan views at level K of FIGS. 10A, 11A, 12A, 13A and 14A, respectively, and FIG. 13D is a plan view at level L of FIG. 13a.

Referring to FIG. 10A to FIG. 10C, a stack 510S is formed by alternately stacking first material layers 510A with second material layers 510B. The first material layers 510A may include an insulating material such as an oxide, and the second material layers 510B may include a material such as a nitride.

Channel structures 530 are formed within channel holes CHH extending through the stack 510S. Each of the channel structures 530 includes a channel layer 530A, a memory layer 530B surrounding the channel layer 530A, and an insulating core 530C surrounded by the channel layer 530A.

Supports 580 are formed in second support holes SPH2 extending through the stack 510S. The supports 580 may have a structure similar to the channel structures 530. Alternatively, the supports 580 may include an insulating material such as an oxide. Alternatively, the supports 580 may include a conductive layer such as tungsten and an insulating layer surrounding the conductive layer.

Support sacrificial layers 540S are formed in first support holes SPH1 extending through the stack 510S. The support sacrificial layers 540S may include a material such as carbon or polysilicon.

A contact hole CTH is formed extending through the stack 510S. For example, the contact hole CTH is formed in a region delineated by the first support holes SPH1 and extending through the stack 510S.

A preliminary contact spacer 550A is formed in the contact hole CTH. A first opening OP1 is formed by etching a lower surface of the preliminary contact spacer 550A, thereby exposing the second material layer 510B. A contact spacer 550 of a contact plug may be formed by etching the lowermost surface of the preliminary contact spacer 550A. A second opening OP2 is formed by selectively removing the second material layer 510B such that the support sacrificial layers 540S are exposed through the first opening OP1.

A first contact sacrificial layer 560S1 is formed in the second opening OP2, the first opening OP1, and the auxiliary contact hole CTH’. For example, the first contact sacrificial layer 560S1 is formed to fill the second opening OP2, the first opening OP1, and the auxiliary contact hole CTH’. The first contact sacrificial layer 560S1 may include a material such as carbon or polysilicon.

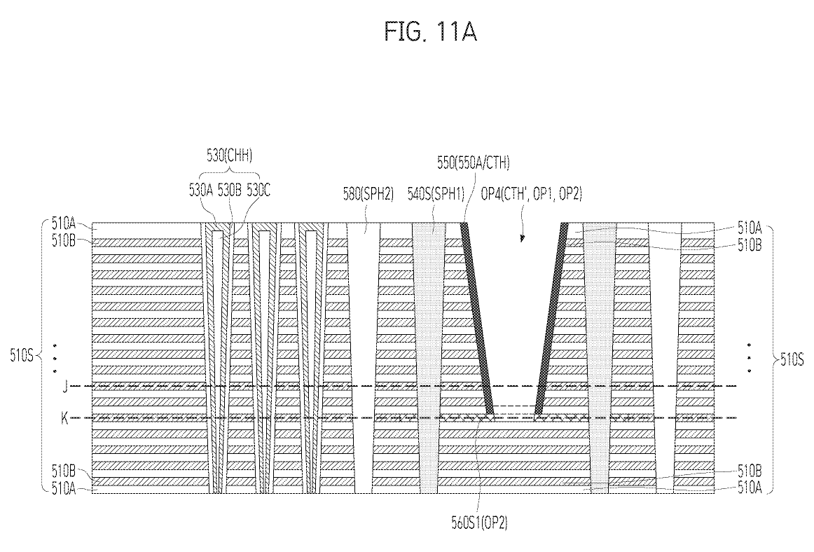

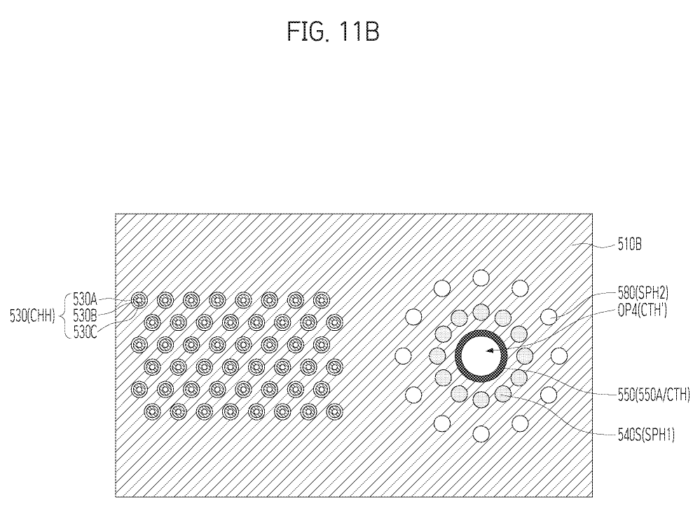

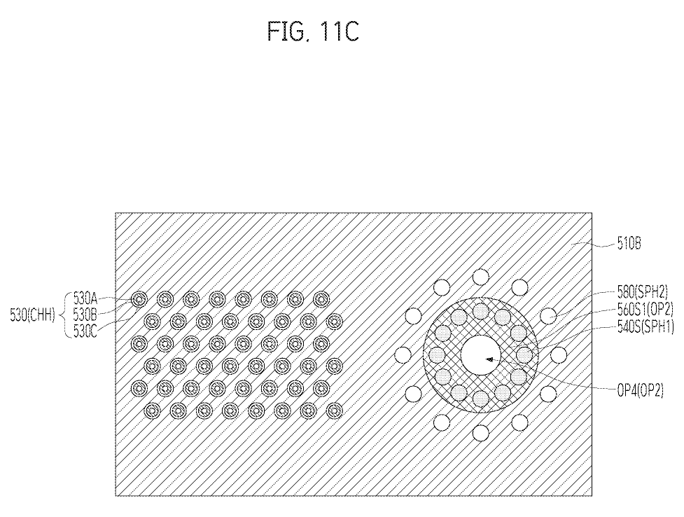

Referring to FIGS. 11A to 11C, a fourth opening OP4 is be formed by removing a portion of the first contact sacrificial layer 560S1. For example, the fourth opening OP4 is formed by removing a portion of the first contact sacrificial layer 560S1 formed in the auxiliary contact hole CTH’, the first opening OP1, and the second opening OP2. A portion of the first contact sacrificial layer 560S1 formed at a location corresponding to the first opening OP1 and a location corresponding to the second opening OP2 is removed. For example, a portion of the first contact sacrificial layer 560S1 formed in the second opening OP2 remains. Auxiliary first openings and auxiliary second openings result from removal of the first contact sacrificial layer 560S1.

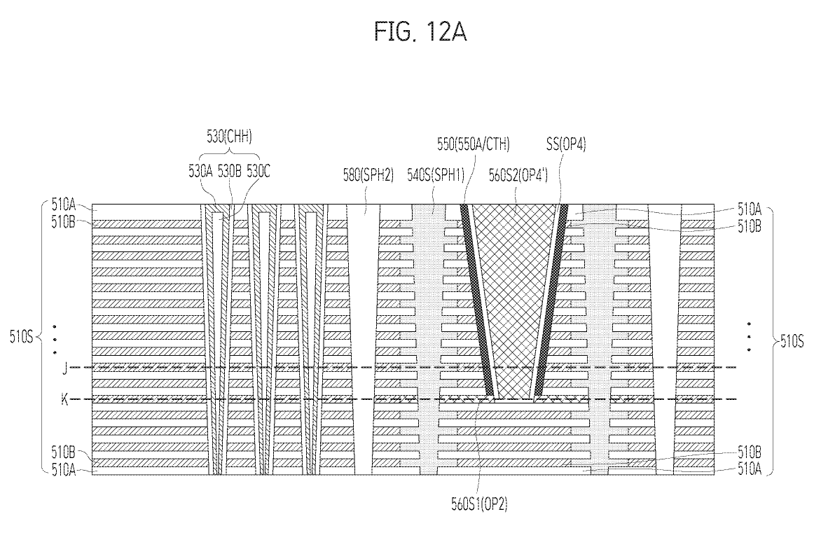

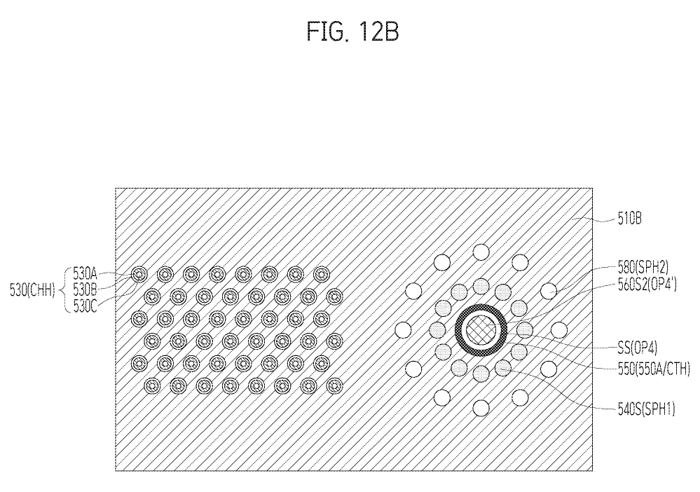

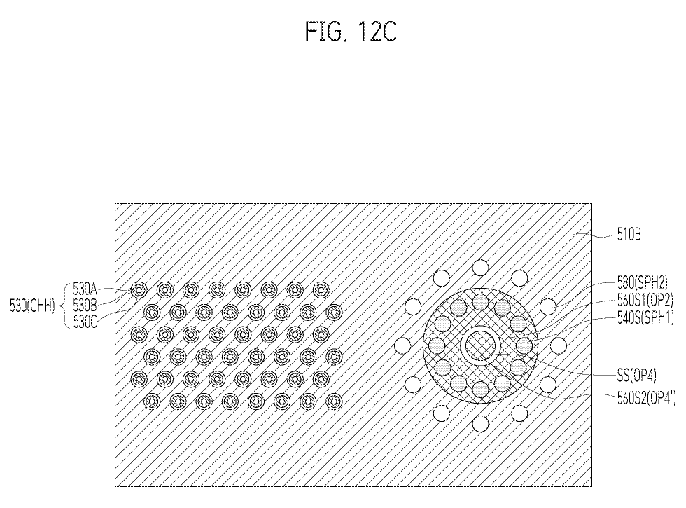

Referring to FIGS. 12A to 12C, a sacrificial spacer SS is formed in the fourth opening OP4. For example, the sacrificial spacer SS is conformally formed along the contact spacer 550 and within the fourth opening OP4. The sacrificial spacer SS may include a material different from a material of the contact spacer 550. For example, the sacrificial spacer SS may include a nitride, and the contact spacer 550 may include an oxide.

A second contact sacrificial layer 560S2 is formed in the auxiliary fourth opening OP4’ that results from forming the sacrificial spacer SS within the fourth opening OP4. For example, the second contact sacrificial layer 560S2 is formed on the sacrificial spacer SS. The second contact sacrificial layer 560S2 may include a material substantially similar to a material included in the first contact sacrificial layer 560S1. For example, the second contact sacrificial layer 560S2 may include a material such as carbon or polysilicon. The present disclosure is not limited to this example, and the second contact sacrificial layer 560S2 may include a material different from the material of the first contact sacrificial layer 560S1.

Referring to FIGS. 13A to 13D, the support sacrificial layers 540S are removed, resulting in auxiliary support holes SPH1’. The auxiliary first support holes SPH1’ are expanded by selectively removing the second material layers 510B through the auxiliary first support holes SPH1’. For example, the auxiliary first support holes SPH1’ are expanded such that the first auxiliary support holes SPH1’ are contiguous or interconnected. In this example, the auxiliary first support holes SPH1’are expanded to form one contiguous auxiliary support hole SPH1. A separation structure 540 is formed within the contiguous auxiliary support hole. The separation structure 540 separates a region where the contact hole CTH is formed from another region such as a gate structure.

A slit SL is formed extending through the stack 510S. Third openings OP3 are formed by removing the second material layers 510B through the slit SL. The separation structure 540 is exposed through at least one of the third openings OP3. The first contact sacrificial layer 560S1 is exposed through one of the third openings OP3. In other words, the first contact sacrificial layer 560S1 remaining in the second opening OP2 is exposed through one of the third openings OP3. In this example, the stack 510S remains in the region where the contact hole CTH is formed within the separation structure 540. The stack 510S located under the contact hole CTH is referred to as a support structure 520.

A fifth opening OP5 is formed by removing the first contact sacrificial layer 560S1 through the third opening OP3 through which the first contact sacrificial layer 560S1 is exposed. For example, the fifth opening OP5 is formed by selectively removing the first contact sacrificial layer 560S1 through the third opening OP3. The sacrificial spacer SS prevents simultaneous removal of the second contact sacrificial layer 560S2 during a process of removing the first contact sacrificial layer 560S1.

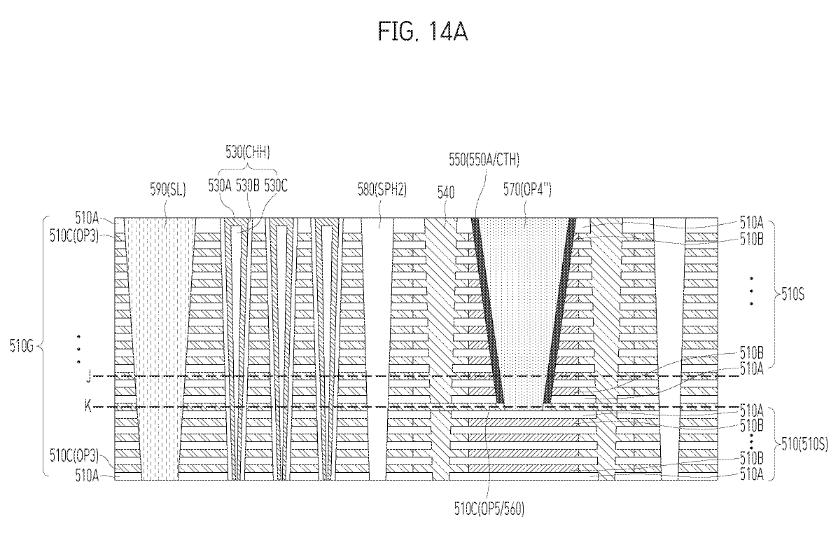

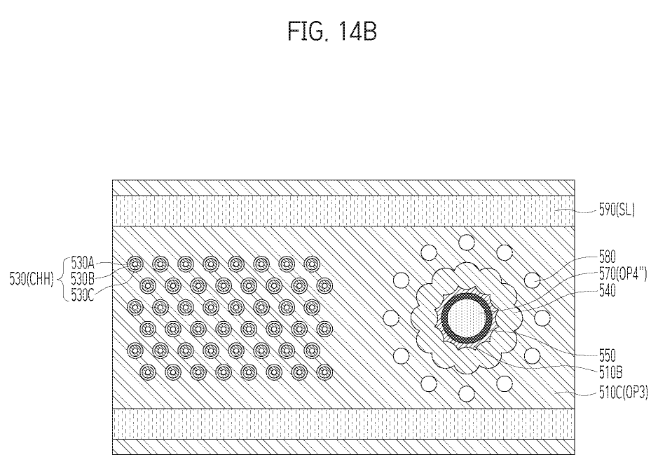

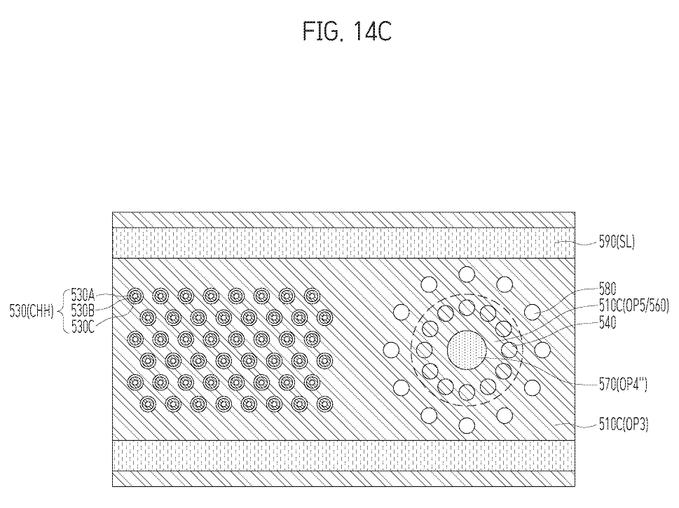

Referring to FIGS. 14A to 14C, third material layers 510C are formed in the third openings OP3. The third material layer 510C is formed in the fifth opening OP5. When forming the third material layers 510C in the third openings OP3, the third material layer 510C may be formed in the fifth opening OP5. The third material layer 510C formed in the fifth opening OP5 is referred to as a contact pattern 560. The third material layers 510C are used as gate lines and may include a conductive material such as tungsten. Thus, a gate structure 510G is formed including the first material layers 510A alternately stacked the third material layers 510C.

A slit structure 590 is formed within the slit SL. The slit structure 590 may include at least one of an insulating material, a semiconductor material, and a conductive material.

A fourth opening OP4’’ is opened by removing the second contact sacrificial layer 560S2 and the sacrificial spacer SS. For example, the fourth opening OP4’’ is opened by sequentially removing the second contact sacrificial layer 560S2 and the sacrificial spacer SS.

A contact plug 570 is formed by forming a conductive material in the fourth opening OP4’’. In this example, the contact plug 570 is connected to one of the third material layers 510C of the gate structure 510G through the contact pattern 560. The conductive material may include a conductive material such as tungsten or polysilicon.

When removing the first contact sacrificial layer formed in the second opening through the contact hole and the first opening, the first contact sacrificial layer formed in the second opening might not be completely removed. When forming a conductive material, the conductive material might not be completely formed in the second opening extending in a horizontal direction. In this example, the contact plug and the third material layer might not be electrically connected, resulting in a defect.

According to an embodiment of the present disclosure, the fourth opening OP4 are formed by removing a portion of the first contact sacrificial layer 560S1 formed in the contact hole CTH, the first opening OP1, and the second opening OP2. A portion of the first contact sacrificial layer 560S1 formed in the second opening OP2 may remain.

A sacrificial spacer SS is formed in the fourth opening OP4, and a second contact sacrificial layer 560S2 is formed on the sacrificial spacer SS. After forming the third openings OP3 to form the gate structure 510G, the fifth opening OP5 is formed by removing the first contact sacrificial layer 560S1 exposed by one of the third openings OP3. In this example, the first contact sacrificial layer 560S1 is removed and none of the first contact sacrificial layer 560S1 remains in the second opening OP2.

Third material layers 510C are formed in the third openings OP3 and the fifth opening OP5. In this example, when forming the third material layers 510C in the third openings OP3, the third material layer 510C is formed in the fifth opening OP5, thus a conductive material is formed in the fifth opening OP5 in the horizontal direction. Thus, the contact plug 570 and the third material layer 510C may be consistently electrically connected.

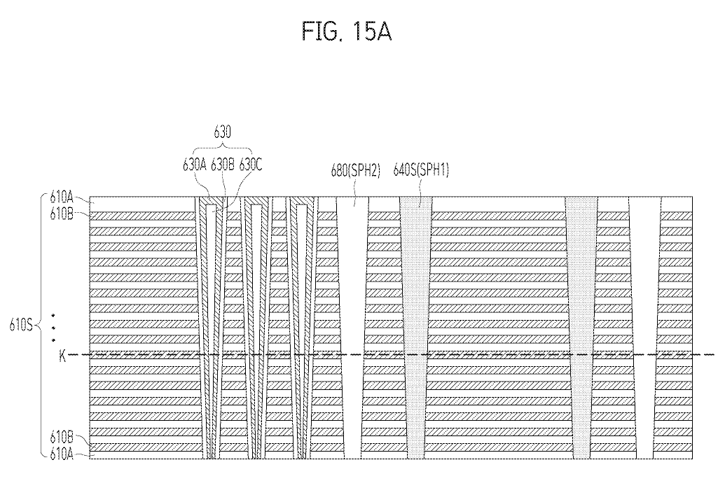

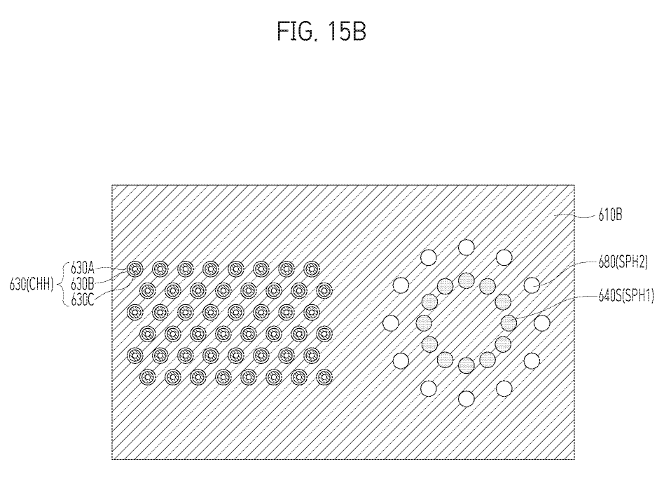

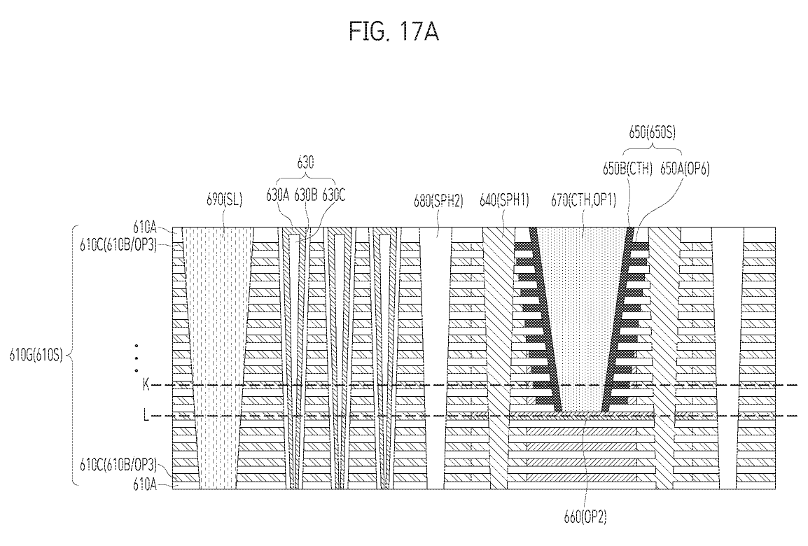

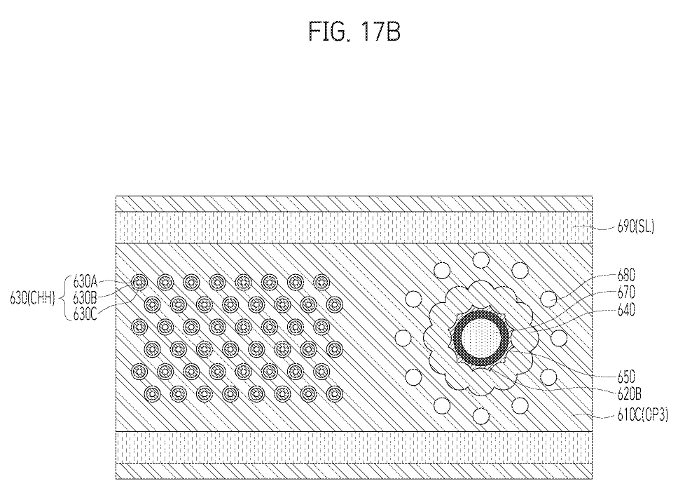

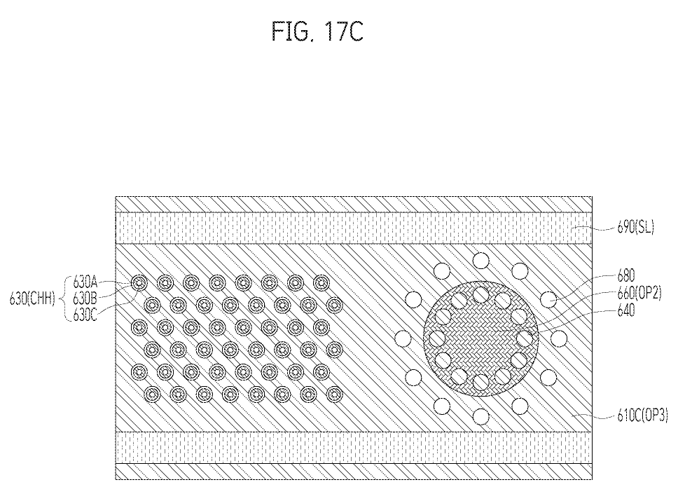

FIGS. 15A, 15B, 16A, 16B, 17A, 17B, and 17C illustrate a semiconductor device formed utilizing a method of manufacturing a semiconductor device according to an embodiment of the present disclosure. FIGS. 15A, 16A, and 17A are cross-sectional views, FIGS. 15B, 16B and 17B are plan views at level K of FIGS. 15A, 16A, and 17A, FIG. 16A, respectively, and FIG. 17C is a plan view at level L of FIG. 17A.

Referring to FIGS. 15A and 15B, a stack 610S is formed by alternately stacking first material layers 610A with second material layers 610B. The first material layers 610A may include an insulating material such as an oxide, and the second material layers 610B may include a material such as a nitride.

Channel structures 630 extending through the stack 610S are formed. Each of the channel structures 630 includes a channel layer 630A, a memory layer 630B surrounding the channel layer 630A, and an insulating core 630C surrounded by the channel layer 630A.

Supports 680 extending through the stack 610S are formed. The supports 680 may have a structure similar to the channel structures 630. Alternatively, the supports 680 may include an insulating material such as an oxide. Alternatively, the supports 680 may include a conductive layer such as tungsten and an insulating layer surrounding the conductive layer.

Support sacrificial layers 640S extending through the stack 610S are formed. The support sacrificial layers 640S may include a material such as carbon or polysilicon.

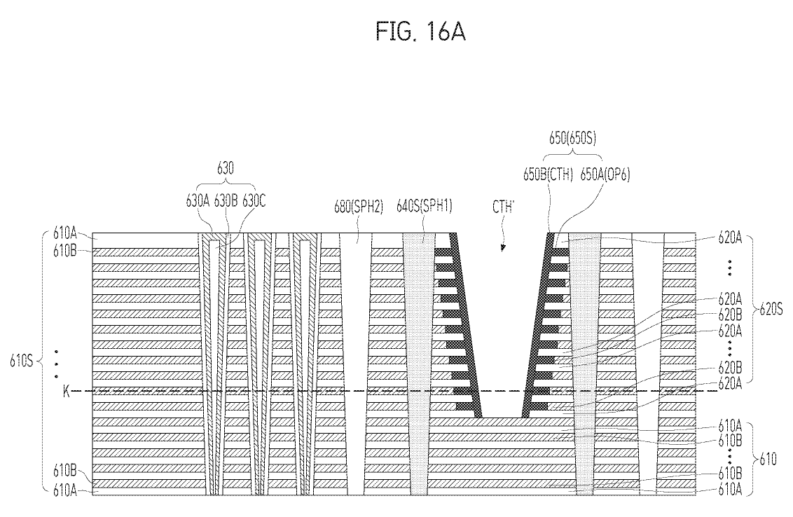

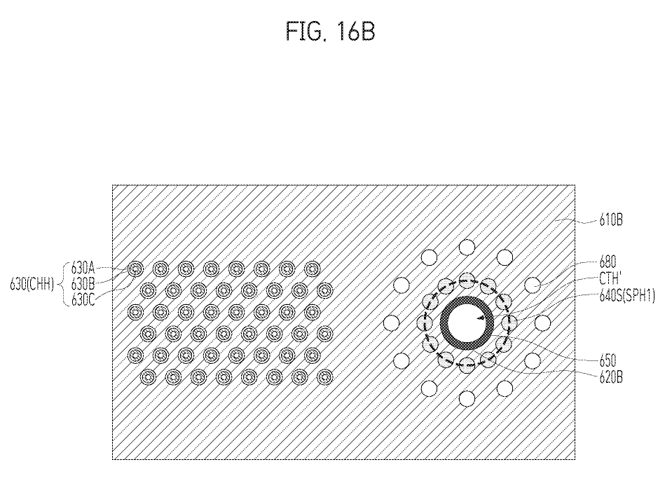

Referring to FIGS. 16A and 16B, a contact hole CTH extending through the stack 610S is formed. For example, the contact hole CTH is formed within a region delineated by the first support holes SPH1 and extending through the stack 610S. The stack 620S within the region includes first insulating layers 620A insulating layers second insulating layers 620B.

Sixth openings OP6 are formed by selectively removing the second material layers 610B through the contact hole CTH. For example, the sixth openings OP6 are formed by removing a portion of the second material layers 610B exposed through the contact hole CTH. The support sacrificial layers 640S are exposed through at least one of the sixth openings OP6.

A preliminary contact spacer 650S is formed in the sixth openings OP6 and the contact hole CTH. The preliminary contact spacer 650S may fill the sixth openings OP6 and is conformally formed adjacent to the stack 620S and within the contact hole CTH. A first opening OP1 is formed, for example, by etching a lowermost surface of the preliminary contact spacer 650A, the second material layer 610B is exposed through the first opening OP1, and the auxiliary contact hole CTH’ results within the contact spacer 650. The contact spacer 650 of a contact plug may be formed by etching the lowermost surface of the preliminary contact spacer 650A. For example, the contact spacer 650 is formed including a body 650B formed in the contact hole CTH, and protrusions 650A protruding or extending from the body 650B are formed in the sixth openings OP6.

Referring to FIGS. 17A to 17C, supports 640, a contact pattern 660, a contact plug 670, and a slit structure 690 are formed. The supports 640, the contact pattern 660, the contact plug 670, and the slit structure 690 may be formed using a method similar to a method used to form the supports 440, the contact pattern 460, the contact plug 470, and the slit structure 490 formed with reference to FIGS. 5A to 9C.

According to an embodiment of the present disclosure, after forming the contact hole CTH, the sixth openings OP6 are formed by selectively removing the second material layers 610B exposed through the contact hole CTH. The contact spacer 650 is formed in the sixth openings OP6.

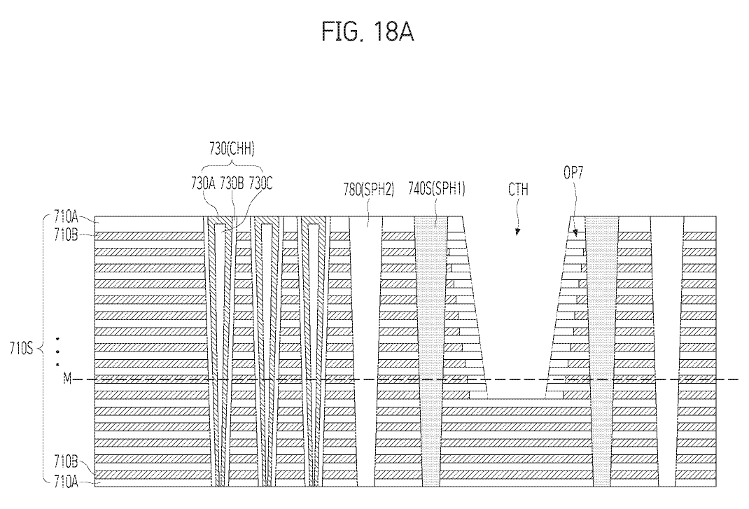

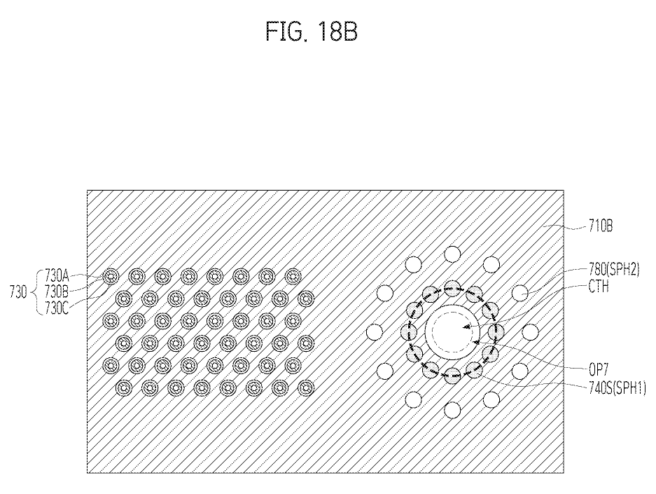

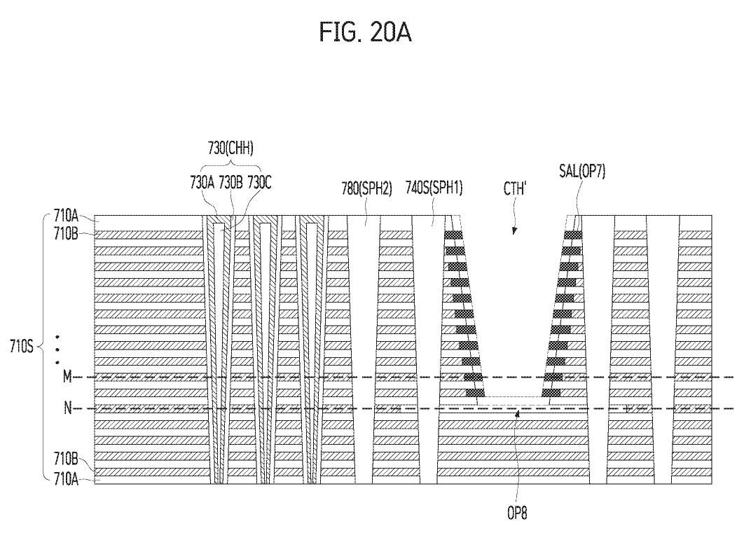

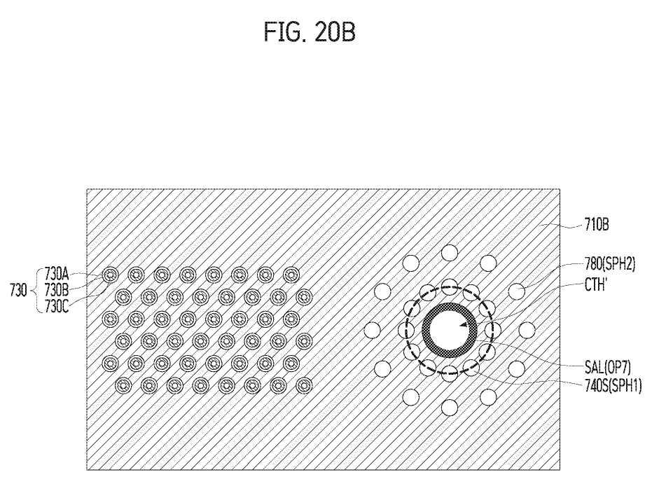

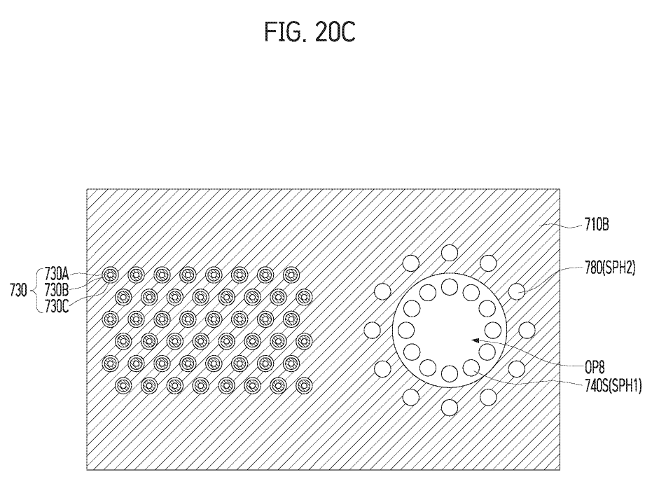

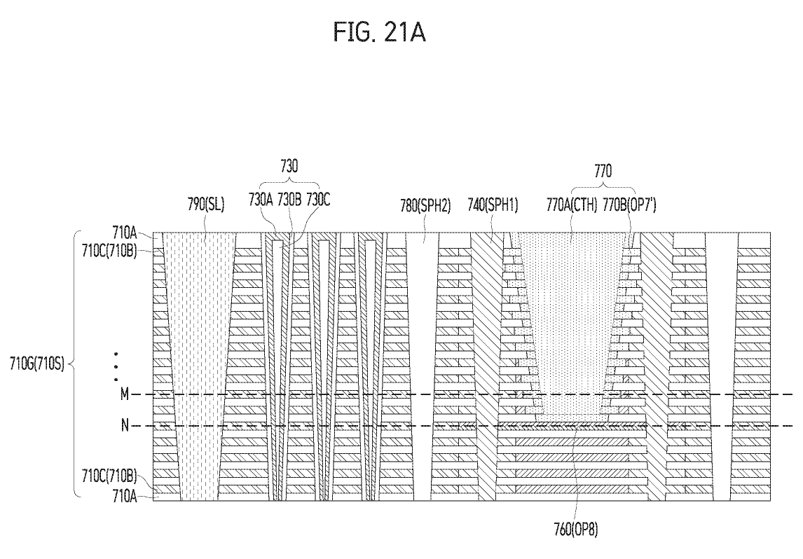

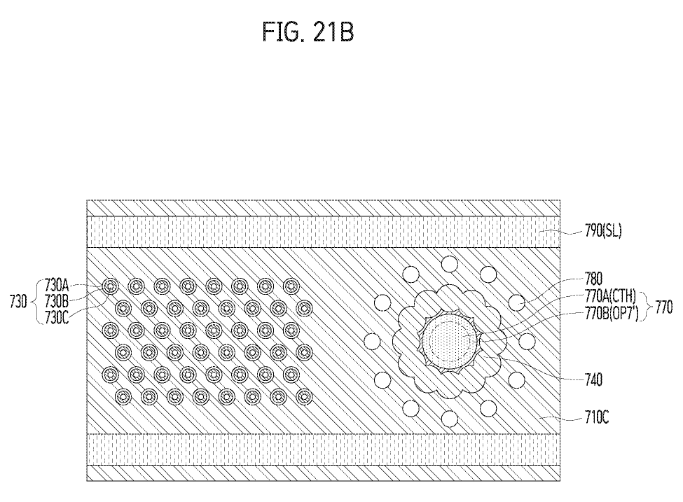

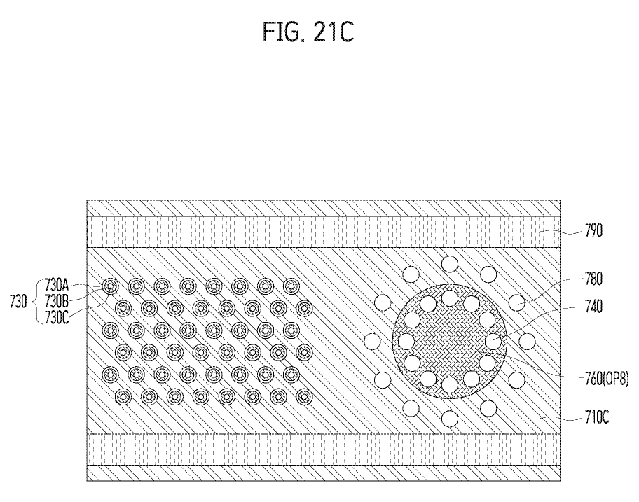

FIGS. 18A. 18B, 19A, 19B, 20A, 20B, 20C, 21A, 21B, and 21C, illustrate a semiconductor device formed utilizing a method of manufacturing a semiconductor device according to an embodiment of the present disclosure. FIGS. 18A, 19A, 20A and 21A are cross-sectional views, FIGS. 18B, 19B, 20B, and 21B are plan views at level M of FIGS. 18A,19A, 20A, and 21A, respectively, and FIGS. 20C and 21C are plan views at level N of FIGS. 20A and 21A, respectively.

Referring to FIGS. 18A and 18B, a stack 710S is formed by alternately stacking first material layers 710A with second material layers 710B. The first material layers 710A may include an insulating material such as an oxide, and the second material layers 710B may include a sacrificial material such as a nitride.

Channel structures 730 extending through the stack 610S are formed. Each of the channel structures 730 include a channel layer 730A, a memory layer 730B surrounding the channel layer 730A, and an insulating core 730C within the channel layer 730A.

Supports 780 extending through the stack 710S are formed. The supports 780 may have a structure similar to the channel structures 730. Alternatively, the supports 780 may include an insulating material such as an oxide. Alternatively, the supports 780 may include a conductive layer such as tungsten and an insulating layer surrounding the conductive layer.

Support sacrificial layers 740S extending through the stack 710S are formed. The support sacrificial layers 740S may include a sacrificial material such as carbon or polysilicon.

A contact hole CTH extending through the stack 710S is formed. For example, the contact hole CTH is formed in a region delineated by the first support holes SPH1 and extending through the stack 710S. At least one of the first material layers 710A is exposed by the contact hole CTH.

Seventh openings OP7 are formed by selectively removing the second material layers 710B. For example, the seventh openings OP7 are formed by selectively removing the second material layers 710B exposed through the contact hole CTH.

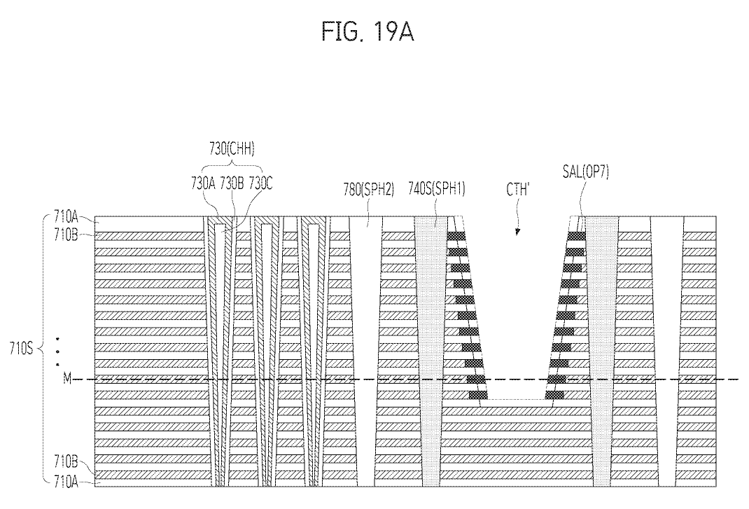

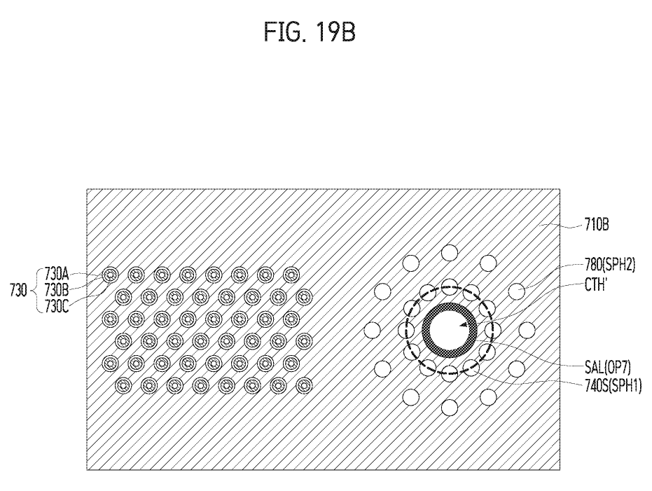

Referring to FIGS. 19A and 19B, sacrificial layers SAL are formed in the seventh openings OP7. For example, the sacrificial layers SAL re selectively deposited on the second material layers 710B exposed through the seventh openings OP7. In this example, the sacrificial layers SAL re selectively formed in the seventh openings OP7, and the sacrificial layers SAL are not formed on a surface of the stack 710S at a lower end of the contact hole CTH. The sacrificial layers SAL may include at least one sacrificial material including polysilicon or carbon. For example, the sacrificial layers SAL may include silicon oxycarbide (SiOC).

The first material layers 710A are selectively removed. For example, the first material layers 710A exposed through the contact hole CTH are selectively removed. The second material layer 710B is exposed by removing a portion of the first material layer 710A exposed on the surface of the stack 710S at a lower end of the contact hole CTH. Sidewalls of the first material layers 710A exposed through the contact hole CTH are etched. A wet etching process may be used. The present disclosure is not limited to this example. An extended contact hole CTH may be used as an auxiliary contact hole CTH’.

Referring to FIGS. 20A to 20C, an eighth opening OP8 is formed by selectively removing the second material layer 710B at level N through the auxiliary contact hole CTH’. For example, the eighth opening OP8 is formed by selectively removing the second material layer 710B such that the support sacrificial layers 740S are exposed through the auxiliary contact hole CTH’. The sacrificial layers SAL prevent the second material layers 710B of a region where the sacrificial layers SAL are formed from etching during a process of forming the eighth opening OP8.

Referring to FIGS. 21A to 21 C, the auxiliary seventh openings OP7’ are opened by removing the sacrificial layers SAL. A contact pattern 760 and a contact plug 770 are formed by forming a conductive material in the auxiliary seventh openings OP7’, the auxiliary contact hole CTH’, and the eighth opening OP8. For example, the contact pattern 760 and the contact plug 770 are formed by forming at least one of tungsten or polysilicon in the auxiliary seventh openings OP7’, the auxiliary contact hole CTH’, and the eighth opening OP8.

A separation structure 740, supports 780, and a slit structure 790 are formed. The separation structure 740, the supports 780, and the slit structure 790 may be formed using a method similar to a method of forming the separation structure 440, the supports 480, and the slit structure 490 as described with reference to FIGS. 5A to 9C.

Referring to FIGS. 3A to 3D, the contact plugs 370 may have different heights. To form the contact plugs with different heights, corresponding contact holes are formed with different heights. For example, after conformally forming contact spacers within contact holes having different heights, the contact spacers are etched such that a surface of the gate structure 320G at a lower end of each of the contact holes is exposed. A dry etching process may be used. The dry etching process includes a method of anisotropic etching by colliding a reactive ion formed in plasma in a vertical direction with an etching target. When the contact holes have different heights, a reach distance and a density distribution of the reactive ion may be non-uniform. As a result, a surface of the gate structure at a lower end of a contact hole of a relatively great height might not be completely exposed (“non-open defect”), and over-etching may occur on a surface of the gate structure 320G at a lower end of a contact hole of a relatively lower height may occur (“punch defect”).

According to an embodiment of the present disclosure, after forming the contact hole CTH, the seventh openings OP7 are formed by selectively removing the second material layers 710B. The sacrificial layers SAL are selectively formed in the seventh openings OP7. In this example, the sacrificial layer SAL is not be formed on the first material layer 710A exposed on the surface of the stack 710S at a lower end of the contact hole CTH. Thus, the first material layer 710A exposed on the surface of the stack 710S at a lower end of the contact hole CTH maintains an exposed state during a process of forming the sacrificial layers SAL. The first material layers 710A exposed through the contact hole CTH are partially etched, and the second material layer 710B on the lower surface of the stack 710S at a lower end of the contact hole CTH is exposed. A wet etching process may be used.

The wet etching process includes an isotropic etching method based on a reaction between an etching object and a chemical solution, and because the chemical solution extends into the contact holes and the reaction proceeds, an etching deviation according to the height of the contact holes is relatively small. Thus, according to an embodiment of the present disclosure, a state in which the surface of the stack at a lower end of a plurality of contact holes is exposed may be maintained, and although the plurality of contact holes have different heights, etching defects such as not-open defects or punch defects may be prevented or minimized by applying the wet etching process.

According to the method of manufacturing, after the seventh openings OP7 are formed through the contact hole CTH, the sacrificial layers SAL are selectively formed in the seventh openings OP7. The first material layer 710A below level N exposed through the contact hole CTH may be maintained in an exposed state. By etching the first material layers 710A exposed through the contact hole CTH using a wet process, the second material layer 710B on the surface of the stack 710S at a lower end of the contact hole CTH is exposed. In this example, although contact holes having different heights are formed, etching deviation may be reduced and etching defects may be prevented.

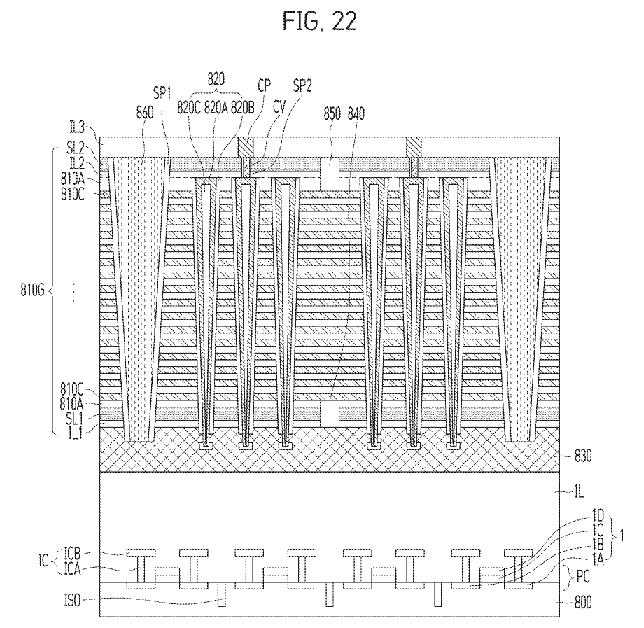

FIG. 22 is a drawing illustrating a semiconductor device according to an embodiment of the present disclosure.

Referring to FIG. 22, the semiconductor device includes a substrate 800, a peripheral circuit PC, an interlayer insulating layer IL, an element isolation layer ISO, an interconnection structure IC, a gate structure 810G, a channel structure 820, a source structure 830, a first separation structure 840, a second separation structure 850, and a slit structure 860. The semiconductor device includes a first spacer SP1, a second spacer SP2, a contact via CV, and a contact plug CP.

The peripheral circuit PC is located on the substrate 800. The peripheral circuit PC includes a transistor 1 and a capacitor, and the like. The transistor 1 includes junctions 1A and 1B, a gate electrode 1D, and a gate insulating layer 1C. The gate insulating layer 1C is located between the gate electrode 1D and the substrate 800. The element isolation layer ISO is formed within the substrate 800, an active region is bordered by the element isolation layer ISO, and the transistor 1 is located in the active region.

The interconnection structure IC may be disposed on the peripheral circuit PC. The interconnection structure IC is located within the interlayer insulating layer IL. The interlayer insulating layer IL may be located on the substrate 800. The interconnection structure IC includes vias ICA and lines ICB.

The interconnection structure IC is connected to the peripheral circuit PC. For example, at least one of the vias ICA is connected to the transistor 1. At least one of the lines ICB is connected to the vias ICA. The interconnection structure IC may include a conductive material such as tungsten. The interlayer insulating layer IL may include an insulating material such as an oxide.

The gate structure 810G is located on the source structure 830. The source structure 830 may be positioned between the peripheral circuit PC and the gate structure 810G as shown in FIG. 22. The gate structure 810G includes insulating layers 810A alternately stacked with conductive layers 810B. The conductive layers 810B are gate lines such as a source selection line, a word line, or a drain selection line. The insulating layers 810A may include an insulating material such as an oxide, and the conductive layers 810B may include a conductive material such as tungsten, molybdenum, or polysilicon.

The gate structure 810G includes a first interlayer insulating layer IL1, a second interlayer insulating layer IL2, a first selection line SL1, and a second selection line SL2. The first interlayer insulating layer IL1 and the first selection line SL1 are located in a region adjacent to the source structure 830. For example, the first interlayer insulating layer IL1 is disposed on the source structure 830, and the first selection line SL1 is located between the first interlayer insulating layer IL1 and the insulating layer 810A. A second interlayer insulating layer IL2 and a second selection line SL2 is located in a region spaced apart from the source structure 830. For example, the second selection line SL2 is located on the uppermost insulating layer 810A, and the second interlayer insulating layer IL2 is located between the insulating layer 810A and the second selection line SL2.

The first selection line SL1 is a drain selection line or a source selection line. The second selection line SL2 is a source selection line or a drain selection line. For example, the first selection line SL1 is a drain selection line, and the second selection line SL2 is a source selection line. For example, the first selection line SL1 is a source selection line, and the second selection line SL2 is a drain selection line. At least one of the first selection line SL1 or the second selection line SL2 may include a material substantially similar to or different from a material of the conductive layers 810B. For example, at least one of the first selection line SL1 or the second selection line SL2 may include polysilicon.

The channel structures 820 extend through the gate structure 810G. For example, the channel structure 820 extends into the source structure 830 through the gate structure 810G. Each of the channel structures 820 includes a channel layer 820A, a memory layer 820B surrounding the channel layer 820A, and an insulating core 820C within the channel layer 820A. The channel layer 820A is electrically connected to the source structure 830.

The first separation structure 840 extends through the gate structure 810G. The first separation structure 840 extends through at least one of the insulating layer 810A, the first selection line SL1, and the first interlayer insulating layer IL1. For example, the first separation structure 840 extends through the first selection line SL1. The first separation structure 840 may separate the first selection line SL1 into two or more first selection lines.

The second separation structure 850 extends through the gate structure 810G. The second separation structure 850 extends through at least one of the insulating layer 810A, the second selection line SL2, and the second interlayer insulating layer IL2. For example, the second separation structure 850 extends through the second selection line SL2. The second separation structure 850 separates the second selection line SL2 into two or more second selection lines. At least one of the first separation structure 840 and the second separation structure 850 may include an oxide. For example, at least one of the first separation structure 840 and the second separation structure 850 may include a material substantially similar to a material of the insulating layer 810A.

The contact plugs CP extend through the third interlayer insulating layer IL3. The third interlayer insulating layer IL3 is located on the gate structure 810G. The contact plugs CP extend through the third interlayer insulating layer IL3 and are connected to the contact vias CV. The contact vias CV are located between the contact plugs CP and the channel structures 820 and connect the contact plugs CP with the corresponding channel structures 820. For example, the contact vias CV extend through the second selection line SL2 and connect the contact plugs CP with corresponding channel structures 820. The second spacers SP cover a sidewall of the contact vias CV. At least one of the contact plugs CP and the contact vias CV may include a conductive material such as tungsten or polysilicon. For example, the contact vias CV may include a material substantially similar to a material of the channel layers 820A. The second spacers SP may include an insulating material such as an oxide.

Although not shown in the drawings, the contact plugs CP are electrically connected to the bit lines and the channel structures 820. The bit lines are located on the contact plugs CP. Although the contact vias CV and the channel structures 820 are separated in this drawing, the contact vias CV and the channel structures 820 may be connected in a single structure. For example, the contact vias CV are integrally connected with the channel layers 820A of the channel structures 820.

The slit structure 860 extends into the source structure 830 through the gate structure 810G. The first spacer SP1 cover a sidewall of the slit structure 860. The slit structure 860 may include at least one of a semiconductor material, a conductive material, and an insulating material. The first spacer SP1 may include an insulating material such as an oxide.

According to the structure described with respect to FIG. 22, the peripheral circuit PC is located under the gate structure 810G. When the peripheral circuit PC is located under a memory array, a size of the semiconductor device may be reduced, thereby improving an integration degree of the semiconductor device. The source structure 830 is located between the peripheral circuit PC and the gate structure 810G. The channel layer 820A extends into the source structure 830 through the gate structure 810G and is connected to the source structure 830.

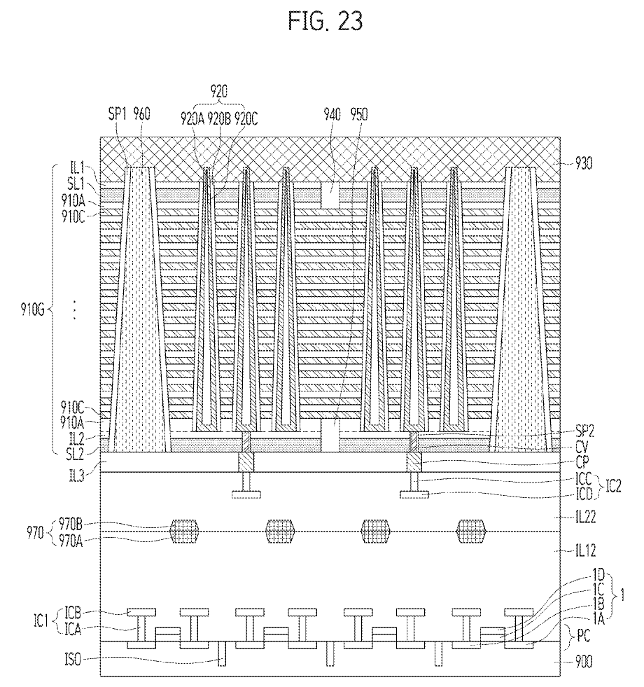

FIG. 23 is a drawing illustrating a semiconductor device according to an embodiment of the present disclosure.

Referring to FIG. 23, the semiconductor device includes a substrate 900, a peripheral circuit PC, a first interlayer insulating layer IL12, a second interlayer insulating layer IL22, an element isolation layer ISO, a first interconnection structure IC1, a second interconnection structure IC2, a gate structure 910G, channel structures 920, a source structure 930, a first separation structure 940, a second separation structure 950, a slit structure 960, and a bonding structure 970. The semiconductor device includes a first spacer SP1, a second spacer SP2, a contact via CV, and a contact plug CP.

The peripheral circuit PC is located on the substrate 900. The peripheral circuit PC includes a transistor 1, a capacitor, and the like. The transistor 1 includes junctions 1A and 1B, a gate electrode 1D, and a gate insulating layer 1C. The gate insulating layer 1C is located between the gate electrode 1D and the substrate 900. The element isolation layer ISO is formed within the substrate 900, an active region is bordered by the element isolation layer ISO, and the transistor 1 is located in the active region.

The first interconnection structure IC may be disposed on the peripheral circuit PC. The first interconnection structure IC1 is located within the first interlayer insulating layer IL12. The first interlayer insulating layer IL12 may be located on the substrate 900. The first interconnection structure IC1 includes first vias ICA and first lines ICB.

The first interconnection structure IC1 is connected to the peripheral circuit PC. For example, at least one of the vias ICA is connected to the transistor 1. At least one of the first lines ICB is connected to the first vias ICA. The first interconnection structure IC1 may include a conductive material such as tungsten. The first interlayer insulating layer IL12 may include an insulating material such as an oxide.

The bonding structure 970 is located on the peripheral circuit PC. For example, the bonding structure 970 is located on the first interconnection structure IC1. The bonding structure 970 includes first bonding pads 970A and second bonding pads 970B. The first bonding pads 970A are located in the second interlayer insulating layer IL22. The second bonding pads 970B are located on the first bonding pads 970A and located in the second interlayer insulating layer IL22. The second interlayer insulating layer IL22 is located on the first interlayer insulating layer IL12. The bonding structure 970 may include a conductive material such as copper.

The gate structure 910G is located over or above the bonding structure 970. The gate structure 910G includes insulating layers 910A alternately stacked with conductive layers 910B. The gate structure 910G includes a first interlayer insulating layer IL1, a second interlayer insulating layer IL2, a first selection line SL1, and a second selection line SL2.

The channel structures 920 extend through the gate structure 910G. For example, the channel structures 920 extend into the source structure 930 through the gate structure 910G. The source structure 930 is located on the gate structure 910G. Each of the channel structures 920 includes a channel layer 920A, a memory layer 920B surrounding the channel layer 920A, and an insulating core 920C in the channel layer 920A. The channel layer 920A is electrically connected to the source structure 930.

The first separation structure 940 extends through the gate structure 910G. For example, the first separation structure 940 extends through the first selection line SL1 and separates the first selection line SL1 into two or more first selection lines. The second separation structure 950 extends through the gate structure 910G. For example, the second separation structure 950 extends through the second selection line SL2 and may separate the second selection line SL into two or more second selection lines.

The second interconnection structure IC2 is located on the bonding structure 970. The second interconnection structure IC2 is located within the second interlayer insulating layer IL22. The second interconnection structure IC2 includes second vias ICC and second lines ICD.

The second interconnection structure IC2 is connected to the channel structures 920. For example, at least one of the second vias ICC may be connected to the channel structures 920. At least one of the second lines ICD is connected to the second vias ICC. At least one of the second lines ICD may be used as a bit line. The second interconnection structure IC2 may include a conductive material such as tungsten.

The contact plugs CP extend through the third interlayer insulating layer IL3. The third interlayer insulating layer IL3 is located under the gate structure 910G. The contact plugs CP extend through the third interlayer insulating layer IL3 and may be connected to the contact vias CV. The contact vias CV extend through the second selection line SL2 and may connect the contact plugs CP with corresponding channel structures 820.

The contact plugs CP electrically connect the channel structures 820 and the bit lines. For example, the contact plugs CP electrically connect the channel structures 820 and the second lines ICD through the contact vias CV.

The slit structure 960 extends through the gate structure 910G. The slit structure 960 may include at least one of a semiconductor material, a conductive material, or an insulating material.

According to the described structures, the semiconductor device may include the bonding structure 970. The bonding structure 970 is located between the peripheral circuit PC and the gate structure 910G. Thus, a peripheral circuit wafer including the peripheral circuit PC and a cell wafer including a memory array may be bonded through the bonding structure 970. By combining and stacking a plurality of peripheral circuit wafers and a plurality of cell wafers using the bonding structure, performance such as a data storage capability of the semiconductor device may be improved.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor device comprising:
a stack including a plurality of first insulating layers alternately stacked with a plurality of second insulating layers;
a contact plug extending through the stack;
a gate structure surrounding the stack and including a plurality of conductive layers alternately stacked with the plurality of first insulating layers;
a separation structure located between the stack and the gate structure; and
a contact pattern extending around the separation structure and electrically connecting the contact plug and a first conductive layer among the plurality of conductive layers.

2. The semiconductor device of claim 1, wherein the separation structure comprises:
a plurality of pillars arranged around the contact plug; and
a plurality of extensions interconnecting the pillars and located at levels corresponding to the plurality of conductive layers except for the first conductive layer.

3. The semiconductor device of claim 2, wherein the plurality of extensions are interconnected in a plane to form a closed region.

4. The semiconductor device of claim 3, wherein one of the plurality of second insulating layers is located at a level corresponding to the plurality of extensions and is located in the closed region.

5. The semiconductor device of claim 2, wherein the contact pattern extends between the plurality of pillars.

6. The semiconductor device of claim 2, wherein the contact pattern is integral with the contact plug.

7. The semiconductor device of claim 1, wherein the contact pattern is integral with the first conductive layer.

8. The semiconductor device of claim 1, further comprising a contact spacer surrounding a sidewall of the contact plug.

9. The semiconductor device of claim 8, wherein the contact spacer includes a body extending through the stack and protrusions protruding from the body toward the gate structure.

10. The semiconductor device of claim 1, wherein the contact plug includes a second body extending through the stack and second protrusions protruding from the second body toward the gate structure.

11. The semiconductor device of claim 1, further comprising:
a peripheral circuit positioned under the gate structure;
a source structure positioned between the gate structure and the peripheral circuit; and
channel structures extending into the source structure through the gate structure.

12. The semiconductor device of claim 1, further comprising:
a peripheral circuit positioned under the gate structure;
a bonding structure positioned between the gate structure and the peripheral circuit;
a source structure positioned above the gate structure; and channel structures extending into the source structure through the gate structure.

13. A semiconductor device comprising:
a stack including a plurality of first insulating layers alternately stacked with a plurality of second insulating layers;
a contact plug extending through the stack;
a gate structure surrounding the stack and including a plurality of conductive layers alternately stacked with the plurality of first insulating layers;
a separation structure located between the stack and the gate structure and including a plurality of pillars arranged around the contact plug and a plurality of extensions interconnecting the pillars; and
a contact pattern extending around the separation structure and electrically connecting the contact plug and a first conductive layer among the plurality of conductive layers.

14. The semiconductor device of claim 13, wherein the plurality of extensions are located at levels corresponding to one of the plurality of conductive layers except for the first conductive layer.

15. The semiconductor device of claim 13, wherein the plurality of extensions is interconnected in a plane to form a closed region.

16. The semiconductor device of claim 15, wherein the plurality of second insulating layers is located at levels corresponding to the plurality of extensions and located in the closed region.

17. The semiconductor device of claim 13, wherein the contact pattern extends between the plurality of pillars.

18. The semiconductor device of claim 13, wherein the contact pattern is electrically connected to the contact plug.

19. The semiconductor device of claim 13, wherein the contact pattern is electrically connected to the first conductive layer.

20. The semiconductor device of claim 13, further comprising a contact spacer surrounding a sidewall of the contact plug.

21. The semiconductor device of claim 20, wherein the contact spacer includes a body extending through the stack and protrusions protruding from the body toward the gate structure.

22. The semiconductor device of claim 13, wherein the contact plug includes a second body extending through the stack and second protrusions protruding from the second body toward the gate structure.

23. The semiconductor device of claim 13, further comprising:
a peripheral circuit positioned under the gate structure;
a source structure positioned between the gate structure and the peripheral circuit; and
channel structures extending into the source structure through the gate structure.

24. The semiconductor device of claim 13, further comprising:
a peripheral circuit positioned under the gate structure;
a bonding structure positioned between the gate structure and the peripheral circuit;
a source structure positioned above the gate structure; and
channel structures extending into the source structure through the gate structure.
